(19) United States
(12) Patent Application Publication
(10) Pub. No.: US 2011/0223397 A1
(43) Pub. Date: Sep. 15, 2011

(54) SEMICONDUCTOR DEVICE AND METHOD FOR MANUFACTURING THE SAME

(76) Inventors: Takashi Kawamori, Ibaraki (JP); Kazuyuki Mitsukura, Ibaraki (JP); Takashi Masuko, Ibaraki (JP); Shigeki Katogi, Ibaraki (JP)

(21) Appl. No.: 13/120,191

(22) PCT Filed: Jun. 25, 2009
(86) PCT No.: PCT/JP2009/061596

§ 371 Date: May 27, 2011

(30) Foreign Application Priority Data
Sep. 22, 2008 (JP) 2008-242765

(51) Int. Cl. B32B 3/00; H01L 21/58

(52) U.S. Cl. 428/195.1; 438/455; 257/E21.505

(57) ABSTRACT

The invention provides a semiconductor device comprising a semiconductor element and an adherend, thermocompression bonded via a patterned photosensitive film adhesive, wherein the water content of the patterned photosensitive film adhesive just before thermocompression bonding is no greater than 1.0 wt %, with the aim of providing a semiconductor device exhibiting excellent heat resistance.

### TECHNICAL FIELD

The present invention relates to a semiconductor device and to a method for producing it.

### BACKGROUND ART

Various forms of semiconductor devices have been proposed in recent years to meet the demands of higher performance and function for electronic components. In such semiconductor devices, patternable photosensitive film adhesives with a photosensitive property are used to adhesively anchor the semiconductor elements to the semiconductor element-mounting support bases (adherends), for their low-stress properties, low-temperature adhesion, moisture-proof reliability and solder reflow resistance, and also to simplify function, form and the assembly process of a semiconductor device.

Photosensitivity is a function whereby sections irradiated with light are chemically altered to become insolubilized or solubilized in aqueous alkali solutions or organic solvents. When a photosensitive film adhesive with a photosensitive property is used, it is exposed through a photomask and treated with a developing solution to form a pattern, whereby thermocompression bonding is achieved between the semiconductor element and the semiconductor element-mounting support base, so that a semiconductor device with a high-definition adhesive pattern can be obtained (see Patent document 1, for example).

### CITATION LIST

### Patent Literature

[Patent document 1] WO/2007/004569

### SUMMARY OF INVENTION

### Problems To Be Solved By the Invention

However, when a photosensitive film adhesive such as described in Patent document 1 and elsewhere is used for production of a semiconductor device, thermocompression bonding defects and the like occur, and the heat resistance of the obtained semiconductor device can be lowered.

As a result of much diligent research, the present inventors have determined that thermocompression bonding defects can occur by the following mechanism.

Specifically, since the photosensitive film adhesive is designed to be soluble in aqueous alkali solutions and organic solvents, it has a relatively high moisture absorptivity or coefficient of water absorption, and readily absorbs moisture during storage and during the semiconductor device assembly process. During thermocompression bonding between the semiconductor element and semiconductor element-mounting support base, the absorbed water gasifies and expands forming bubbles, which can result in thermocompression bonding defects.

It was also found that the voids formed in the adhesive due to the bubbles can potentially lower the heat resistance of the semiconductor device.

In light of these circumstances, it is an object of the present invention to provide a semiconductor device with excellent heat resistance, as well as a method for producing such semiconductor device that allows the semiconductor device to be produced with minimal problems such as thermocompression bonding defects.

### Means For Solving the Problems

The present invention provides a semiconductor device comprising a semiconductor element and an adherend thermocompression bonded via a patterned photosensitive film adhesive, wherein the water content of the patterned photosensitive film adhesive just before thermocompression bonding is no greater than 1.0 wt %. The semiconductor device has excellent heat resistance.

Although the reason for the effect obtained by the semiconductor device of the invention is not fully understood, the present inventors have conjectured as follows.

Specifically, producing an electronic component from a semiconductor device requires a curing step in which the adhesive is cured and solder reflow step, and high-temperature treatment is necessary for these steps. In the semiconductor device of the invention, the water content is limited to below a prescribed value so that it is possible to prevent peeling of the adhesive layer by the gasification and expansion that occur when the water is exposed to high temperature, and it is presumably for this reason that the excellent heat resistance is exhibited.

The adherend is preferably a semiconductor element or protective glass.

The photosensitive film adhesive preferably comprises at least a (A) thermoplastic resin and a (B) thermosetting resin, and also preferably further comprises a (C) radiation-polymerizable compound and a (D) photoinitiator.

The (A) thermoplastic resin is preferably an alkali-soluble resin. The alkali-soluble resin is preferably a polyimide resin having a carboxyl and/or hydroxyl group in the molecule, from the viewpoint of obtaining particularly excellent developability and heat resistance.

The (B) thermosetting resin is preferably an epoxy resin, to allow excellent adhesive force at high temperature to be imparted.

The patterned photosensitive film adhesive is preferably formed by an adhesive layer-forming step in which an adhesive layer comprising the photosensitive film adhesive is formed on an adherend (preferably a semiconductor wafer), an exposure step in which the adhesive layer is exposed with a prescribed pattern, a developing step in which the exposed adhesive layer is developed with an aqueous alkali solution, and a water content-adjusting step in which the water content of the developed adhesive layer is adjusted.

The invention also provides a method for producing a semiconductor device, comprising a patterning step in which photosensitive film adhesive formed on the circuit side of a semiconductor element is patterned by exposure and development, a water content-adjusting step in which the water content of the patterned photosensitive adhesive is adjusted, and a thermocompression bonding step in which an adherend is directly bonded by thermocompression bonding to the patterned photosensitive adhesive, wherein in the water content-adjusting step, water content adjustment is carried out in which the water content after pattern formation of the patterned photosensitive film adhesive on a PET substrate is adjusted to no greater than 1.0 wt %, as well as a semiconductor device produced by the production method.

The adherend is preferably a semiconductor element or protective glass.

The water content adjustment is preferably heat treatment. The heat treatment may be carried out under conditions of, for example, 80-200° C., for 5 seconds-30 minutes.

The photosensitive film adhesive preferably comprises at least a (A) thermoplastic resin and a (B) thermosetting resin, and also preferably further comprises a (C) radiation-polymerizable compound and a (D) photoinitiator.

The (A) thermoplastic resin is preferably an alkali-soluble resin. The alkali-soluble resin is preferably a polyimide resin having a carboxyl and/or hydroxyl group in the molecule, from the viewpoint of obtaining particularly excellent developability and heat resistance.

The (B) thermosetting resin is preferably an epoxy resin, to allow excellent adhesive force at high temperature to be imparted.

### Effect of the Invention

According to the invention it is possible to provide a semiconductor device with excellent heat resistance, as well as method for producing such semiconductor device that allows the semiconductor device to be produced with minimal problems such as thermocompression bonding defects.

### BRIEF DESCRIPTION OF DRAWINGS

FIG. 1 is an end view of an embodiment of a method for producing a semiconductor device.

FIG. 2 is an end view of an embodiment of a method for producing a semiconductor device.

FIG. 3 is a plan view of an embodiment of a method for producing a semiconductor device.

FIG. 4 is a plan view of an embodiment of a method for producing a semiconductor device.

FIG. 5 is a plan view of an embodiment of a method for producing a semiconductor device.

FIG. 6 is a plan view of an embodiment of a method for producing a semiconductor device.

FIG. 7 is a plan view of an embodiment of a method for producing a semiconductor device.

FIG. 8 is an end view showing an embodiment of a semiconductor wafer with an adhesive layer.

FIG. 9 is a top view showing an embodiment of an adhesive pattern.

FIG. 10 is an end view of FIG. 9 along line VI-VI.

FIG. 11 is a top view showing an embodiment of an adhesive pattern.

FIG. 12 is an end view of FIG. 11 along line VIII-VIII.

FIG. 13 is a top view showing the state of cover glass bonded to a semiconductor wafer through an adhesive pattern.

FIG. 14 is an end view of FIG. 13 along line X-X.

FIG. 15 is a top view showing the state of cover glass bonded to a semiconductor wafer through an adhesive pattern.

FIG. 16 is an end view of FIG. 15 along line XII-XII.

FIG. 17 is an end view showing an embodiment of a semiconductor device.

FIG. 18 is an end view showing an embodiment of a semiconductor device.

FIG. 19 is a cross-sectional view showing an embodiment of a CCD camera module.

FIG. 20 is a cross-sectional view showing an embodiment of a CCD camera module.

FIG. 21 is a cross-sectional view showing an embodiment of a semiconductor device.

FIG. 22 is a cross-sectional view showing an embodiment of a method for producing a semiconductor device.

FIG. 23 is a cross-sectional view showing an embodiment of a method for producing a semiconductor device.

FIG. 24 is a cross-sectional view showing an embodiment of a method for producing a semiconductor device.

FIG. 25 is a cross-sectional view showing an embodiment of a method for producing a semiconductor device.

FIG. 26 is a cross-sectional view showing an embodiment of a method for producing a semiconductor device.

### EMBODIMENTS FOR CARRYING OUT THE INVENTION

A preferred mode for carrying out the invention will now be described in detail. However, the present invention is not limited to the following description.

The semiconductor device of the invention comprises a semiconductor element and an adherend thermocompression bonded via a patterned photosensitive film adhesive, wherein the water content of the patterned photosensitive film adhesive just before thermocompression bonding is no greater than 1.0 wt %.

The method for producing a semiconductor device according to the invention comprises a patterning step in which a photosensitive film adhesive formed on the circuit side of a semiconductor element is patterned by exposure and development, a water content-adjusting step in which the water content of the patterned photosensitive adhesive is adjusted, and a thermocompression bonding step in which an adherend is directly bonded by thermocompression bonding to the patterned photosensitive adhesive, wherein in the water content-adjusting step, water content adjustment is carried out in which the water content after pattern formation of the patterned photosensitive film adhesive on a PET substrate is adjusted to no greater than 1.0 wt %.

The water adjustment is more preferably treatment in which the water content after pattern formation, in the patterned photosensitive film adhesive on the PET substrate, is limited to no greater than 0.7 wt %, and even more preferably no greater than 0.5 wt %.

Without water content adjustment, the water remaining in the photosensitive film adhesive results in foaming due to gasification and expansion of the water during thermocompression bonding between the semiconductor element and adherend, potentially causing problems during semiconductor device production, such as peeling between the semiconductor element and protective glass that have been contact bonded. When the remaining water is exposed to high temperature in the curing and solder reflow steps, it becomes a cause of peeling between the adhesive and adherend due to gasification and expansion.

It is also highly possible for the voids, formed in the adhesive due to the bubbles, to lower the heat resistance of the semiconductor device.

The water content of the patterned photosensitive film adhesive can be measured using an AQV2100CT water measuring apparatus by Hiranuma Sangyo Corp., for example.

According to the invention, the water content is defined as follows.

An adhesive sheet, comprising a photosensitive film adhesive with a thickness of 50 μm formed on a PET substrate, with a transparent PET film additionally attached as a cover film, is cut to a size of 150 mm×150 mm. A mask is placed over the cut adhesive sheet, and a high-precision parallel exposure apparatus (product of Orc Manufacturing Co., Ltd.) is used for exposure (ultraviolet irradiation) under conditions with an exposure dose of 1000 mJ/cm², followed by heating at 80° C. for 30 seconds. Next, the PET film is released from one side and a spray developer by Yako Co., Ltd. is used for development (developing solution: 2.38% tetramethylammonium hydride (TMAH), 27° C., 0.18 MPa spray pressure; washing: purified water, 23° C., 0.02 MPa spray pressure). A photosensitive adhesive pattern is formed in this manner on the PET substrate, and then the TMAH adhering to the film is washed off with purified water for 6 minutes. This is allowed to stand at room temperature for 30 minutes, the PET substrate is released, and an AQV2100CT water measuring apparatus by Hiranuma Sangyo Corp. is used to measure the water content of the patterned photosensitive film adhesive. The “water content” according to the invention is the water content at this point.

Also, “water content adjustment” according to the invention refers to adjustment of this water content to no greater than 1.0 wt %. The conditions for the water content adjustment are appropriately adjusted according to the type of film. For example, when the photosensitive film adhesive contains fluorine atoms, the absorbed water content is lower and the affinity with the absorbed water is also low, and in such cases the water content adjustment may be spin drying or the like involving discharge of water. In other cases, the conditions are preferably modified as appropriate for the type of film. When heat treatment is carried out as the water content adjustment, it is preferably at 80-200° C. for 5 seconds-30 minutes, more preferably at 100° C.-200° C. for 30 seconds-20 minutes and most preferably at 120° C.-200° C. for 1-10 minutes.

When heat treatment is carried out as the water content adjustment, a temperature of below 80° C. for less than 5 seconds will tend to cause the water content of the pattern-formed photosensitive film adhesive formed on the PET substrate to increase to 1.0 wt % or greater, while if the heating conditions exceed 200° C. and 30 minutes, thermosetting of the patterned photosensitive film adhesive will proceed, leading to impairment of the hot flow property during thermocompression bonding.

When such heat treatment is carried out, for example, the patterned photosensitive film adhesive formed on the adherend may be placed on multiple polyethylene fluoride-based fiber sheets or the like, and the polyethylene fluoride-based fiber sheets placed on a hot plate and heated with prescribed temperature and time conditions.

This water content adjustment can reduce bonding defects caused by void generation during thermocompression bonding, thermosetting and solder reflow, and can allow a heat-resistant semiconductor device to be produced.

The thermocompression bonding between the semiconductor element and adherend may be carried out, for example, by contact bonding for 0.1-300 seconds with a heating temperature of 20-250° C. and a load of 0.01-20 kgf.

The patterned photosensitive film adhesive is preferably formed by an adhesive layer-forming step in which an adhesive layer comprising the photosensitive film adhesive is formed on an adherend, an exposure step in which the adhesive layer is exposed with a prescribed pattern, and a developing step in which the exposed adhesive layer is developed with an aqueous alkali solution.

In the adhesive layer-forming step, the photosensitive film adhesive-forming composition (varnish) may, for example, be laminated onto an adherend such as a silicon wafer by pressing with a roll at a temperature of preferably 20-150° C., to form adhesive layer.

In the exposure step, for example, a photomask with a prescribed pattern formed thereon may be placed on the adhesive layer, and a high-precision parallel exposure apparatus (product of Orc Manufacturing Co., Ltd.) used for ultraviolet irradiation (exposure) under conditions with an exposure dose of 100-1000 mJ/cm². The adhesive pattern may be formed by direct pattern-rendering exposure of the adhesive layer using direct writing exposure technology. If necessary, the exposure step may be followed by heating at 40° C.-120° C. for 5-30 seconds.

In the developing step, for example, a 1.0-5.0% and preferably 2.38% solution of tetramethylammonium hydride (TMAH) may be used for spray development, to form the adhesive layer as a pattern. The exposed sections are removed if the photosensitive film adhesive is a positive type, whereas the exposed sections remain if it is a negative type.

The line width of the pattern is preferably in the range of 0.01 mm-20 mm.

There are no particular restrictions on the shape of the pattern, but for example, it may be in the form of a frame, lines or through-holes, with a frame shape being preferred to obtain a stable patterned adhesive.

The photosensitive film adhesive preferably comprises at least a (A) thermoplastic resin and a (B) thermosetting resin, and also preferably further comprises a (C) radiation-polymerizable compound and a (D) photoinitiator.

The (A) thermoplastic resin is not particularly restricted so long as it is soluble in alkali developing solutions, and examples include one or more resins selected from the group consisting of polyimide resins, polyamide resins, polyamideimide resins, polyetherimide resins, polyurethaneimide resins, polyurethaneamideimide resins, siloxanepolyimide resins, polyesterimide resins and their copolymers, as well as phenoxy resins, polysulfone resins, polyethersulfone resins, polyphenylene sulfide resins, polyester resins, polyetherketone resins, (meth)acrylic copolymers and the like, among which polyimide resins are preferred to obtain both developability and heat resistance, and polyimide resins with alkali-soluble groups such as carboxyl and/or hydroxyl groups on the side chains or ends are more preferred.

A polyimide resin may be obtained, for example, by condensation reaction of a tetracarboxylic dianhydride and diamine by a known process. Specifically, the compositional ratio is adjusted so that the tetracarboxylic dianhydride and diamine are in equimolar amounts in the organic solvent, or if necessary so that the total of diamines is in the range of preferably 0.5-2.0 mol and more preferably 0.8-1.0 mol with respect to 1.0 mol as the total tetracarboxylic dianhydrides (with any desired order of addition of the components), and addition reaction is conducted with a reaction temperature of no higher than 80° C. and preferably 0-60° C. The viscosity of the reaction mixture will gradually increase as the reaction proceeds, forming polyamide acid as the polyimide resin precursor. In order to prevent reduction in the properties of the adhesive, the tetracarboxylic dianhydride is preferably one that has been subjected to recrystallizing purifying treatment with acetic anhydride.

If the total diamine content exceeds 2.0 mol with respect to 1.0 mol as the total tetracarboxylic dianhydrides, in the compositional ratio of the tetracarboxylic dianhydride and diamine components for the condensation reaction, the amount of amine-terminal polyimide oligomers in the obtained polyimide resin will tend to be greater, and if the total diamine content is less than 0.5 mol the amount of acid-terminal polyimide oligomers will tend to be greater, while in both cases the weight-average molecular weight of the polyimide resin will be lowered, and the properties of the adhesive, including the heat resistance, will tend to be reduced.

The charging compositional ratio for the tetracarboxylic dianhydrides and diamines is preferably determined as appropriate so that the weight-average molecular weight of the obtained polyimide resin is 10,000-300,000.

The polyimide resin may be obtained by dehydrating cyclization of the reaction product (polyamide acid). Dehydrating cyclization can be accomplished by thermal cyclization using heat treatment or by chemical cyclization using a dehydrating agent.

There are no particular restrictions on tetracarboxylic dianhydrides to be used as starting materials for the polyimide resin, and examples include pyromellitic acid dianhydride, 3,3′,4,4′-biphenyltetracarboxylic dianhydride, 2,2′,3,3′-biphenyltetracarboxylic dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic dianhydride, bis(3,4-dicarboxyphenyl)ether dianhydride, benzene-1,2,3,4-tetracarboxylic dianhydride, 3,4,3′,4′-benzophenonetetracarboxylic dianhydride, 2,3,2′,3′-benzophenonetetracarboxylic dianhydride, 3,3,3′,4′-benzophenonetetracarboxylic dianhydride, 1,2,5,6-naphthalenetetracarboxylic dianhydride, 1,4,5,8-naphthalenetetracarboxylic dianhydride, 2,3,6,7-nephthalenetetracarboxylic dianhydride, 1,2,4,5-naphthalenetetracarboxylic dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, phenanthrene-1,8,9,10-tetracarboxylic dianhydride, pyrazine-2,3,5,6-tetracarboxylic dianhydride, thiophene-2,3,5,6-tetracarboxylic dianhydride, 2,3,3′,4′-biphenyltetracarboxylic dianhydride, 3,4,3′,4′-biphenyltetracarboxylic dianhydride, 2,3,2′,3′-biphenyltetracarboxylic dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic dianhydride, 1,2,3,4-butanetetracarboxylic dianhydride, decahydronaphthalene-1,4,5,8-tetracarboxylic dianhydride, 4,8-dimethyl-1,2,3,5,6,7-hexahydronaphthalene-1,2,5,6-tetracarboxylic dianhydride, cyclopentane-1,2,3,4-tetracarboxylic dianhydride, pyrrolidine-2,3,4,5-tetracarboxylic dianhydride, 1,2,3,4-cyclobutanetetracarboxylic dianhydride, bis(exo-bicyclo[2.2.1]heptane-2,3-dicarboxylic dianhydride, bicyclo-[2.2.2]-oct-7-ene-2,3,5,6-tetracarboxylic dianhydride, 2,2-bis(3,4-dicarboxyphenyl)propane dianhydride, 2,2-bis[4-(3,4-dicarboxyphenyl)phenyl]propane dianhydride, 2,2-bis(3,4-dicarboxyphenyl)hexafluoropropane dianhydride, 2,2-bis[4-(3,4-dicarboxyphenyl)phenyl]hexafluoropropane dianhydride, 4,4′-bis(3,4-dicarboxyphenoxy)diphenyl sulfide dianhydride, 1,4-bis(2-hydroxyhexafluoroisopropyl)benzenebis(trimellitic anhydride), 1,3-bis(2-hydroxyhexafluoroisopropyl)benzenebis(trimellitic anhydride), 5-(2,5-dioxotetrahydrofuryl)-3-methyl-3-cyclohexene-1,2-dicarboxylic dianhydride, tetrahydrofuran-2,3,4,5-tetracarboxylic dianhydride, and tetracarboxylic dianhydrides represented by the following formula (I).

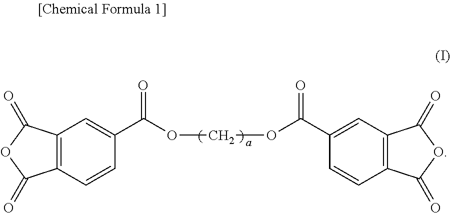

[In the formula, a represents an integer of 2-20.]

A tetracarboxylic dianhydride represented by formula (I) can be synthesized from trimellitic anhydride monochloride and its corresponding diol, for example, and specifically there may be mentioned 1,2-(ethylene)bis(trimellitate anhydride), 1,3-(trimethylene)bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene)bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride) and 1,18-(octadecamethylene)bis(trimellitate anhydride).

As tetracarboxylic dianhydrides there are preferred tetracarboxylic dianhydrides represented by the following formula (II) or (III), from the viewpoint of imparting satisfactory solubility in the solvent and satisfactory moisture-proof reliability.

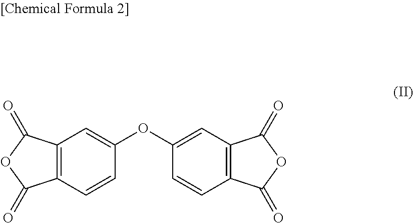

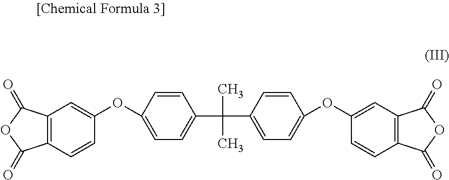

These tetracarboxylic dianhydrides may be used alone or in combinations of two or more.

The diamines used as starting materials for the polyimide resin preferably include aromatic diamines represented by any of the following formulas (IV) to (VII). The diamines represented by the following formulas (IV) to (VII) preferably constitute 1-70 mol % of the total diamines. It will thus be possible to prepare a polyimide resin that is soluble in the alkali developing solution.

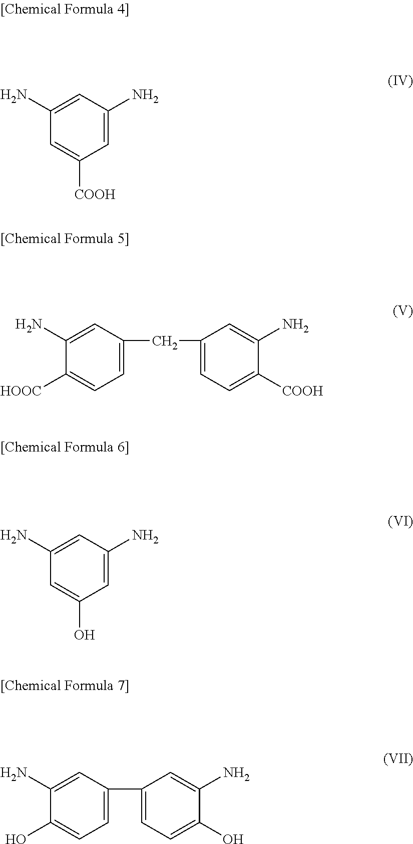

There are no particular restrictions on other diamines to be used as starting materials for the polyimide resin, and examples include aromatic diamines such as o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, bis(4-amino-3,5-dimethylphenyl)methane, bis(4-amino-3,5-diisopropylphenyl)methane, 3,3′-diaminodiphenyldifluoromethane, 3,4′-diaminodiphenyldifluoromethane, 4,4′-diaminodiphenyldifluoromethane, 3,3′-diaminodiphenylsulfone, 3,4′-diaminodiphenylsulfone, 4,4′-diaminodiphenylsulfone, 3,3′-diaminodiphenyl sulfide, 3,4′-diaminodiphenyl sulfide, 4,4′-diaminodiphenyl sulfide, 3,3′-diaminodiphenylketone, 3,4′-diaminodiphenylketone, 4,4′-diaminodiphenylketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminophenoxy)phenyl)sulfide, bis(4-(4-aminophenoxy)phenyl)sulfide, bis(4-(3-aminophenoxy)phenyl)sulfone, bis(4-(4-aminophenoxy)phenyl)sulfone, 3,3′-dihydroxy-4,4′-diaminobiphenyl and 3,5-diaminobenzoic acid, 1,3-bis(aminomethyl)cyclohexane, 2,2-bis(4-aminophenoxyphenyl)propane, 2,2-bis(3-amino-4-hydroxyphenyl)hexafluoropropane, aliphatic etherdiamines represented by the following formula (VIII), aliphatic diamines represented by the following formula (X), and siloxanediamines represented by the following formula (XI).

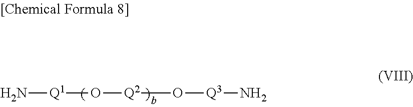

[In the formula, Q¹, Q² and Q³ each independently represent a C1-10 alkylene group, and b represents an integer of 2-80.]

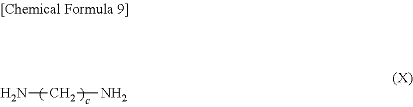

[In the formula, c represents an integer of 5-20.]

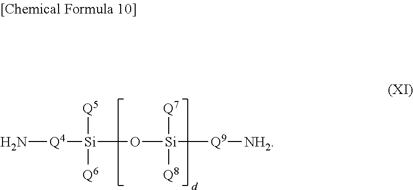

[In the formula, Q⁴ and Q⁹ each independently represent a C1-5 alkylene or optionally substituted phenylene group, Q⁵, Q⁶, Q⁷ and Q⁸ each independently represent a C1-5 alkyl, phenyl or phenoxy group, and d represents an integer of 1-5.]

Specific aliphatic etherdiamines represented by formula (VIII) include aliphatic diamines represented by the following formulas:

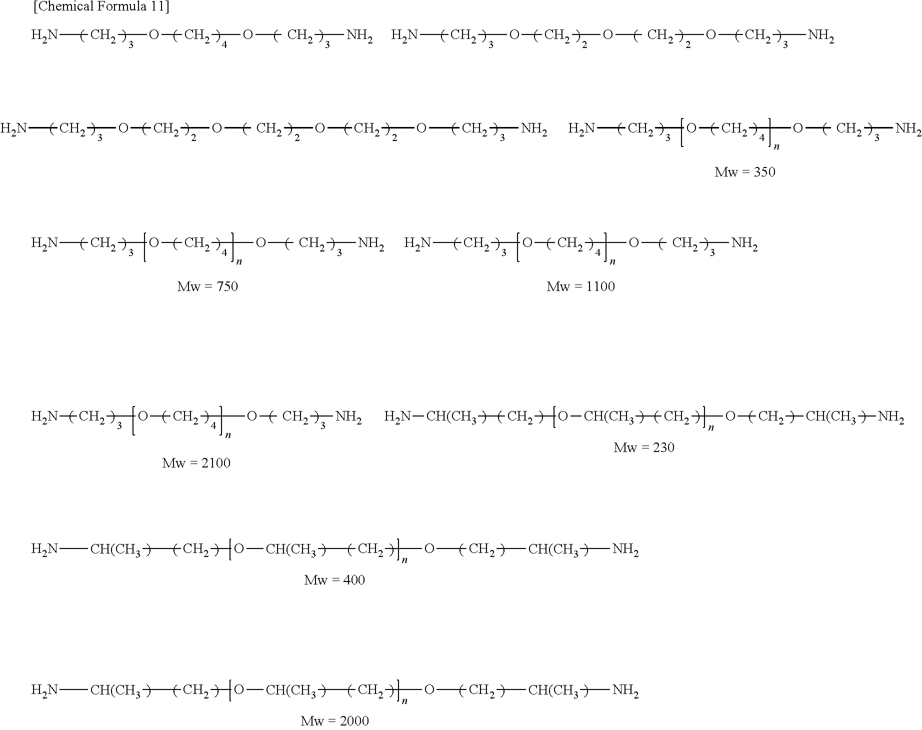

and aliphatic etherdiamines represented by the following formula (IX).

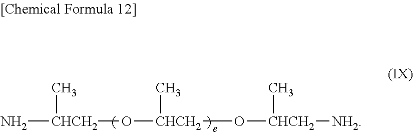

[In the formula, e represents an integer of 0-80.]

Specific aliphatic diamines represented by formula (X) above include 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,11-diaminoundecane, 1,12-diaminododecane and 1,2-diaminocyclohexane.

Specific siloxanediamines represented by chemical formula (XI) include those wherein d in formula (XI) is 1, such as 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane and 1,3-dimethyl-1,3-dimethoxy-1,3-bis(4-aminobutyl)disiloxane.

They also include those wherein d is 2, such as 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane and 1,1,3,3,5,5-hexapropyl-1,5-bis(3-aminopropyl)trisiloxane.

The other diamine used as a starting material for the polyimide resin is preferably one containing a fluorine atom, and more preferably 2,2-bis(3-amino-4-hydroxyphenyl)hexafluoropropane (hereinafter referred to as “BIS-AP-AF”). Using a diamine containing a fluorine atom will allow lower adjustment of the water content of the photosensitive film adhesive. It is believed that the presence of fluorine atoms in the molecules reduces the degree of water that is absorbed, and since it also has low affinity with the absorbed water, the water evaporates more easily.

These diamines may be used alone or in combinations of two or more.

The above-mentioned polyimide resins may be used alone, or if necessary they may be used as mixtures (blends) of two or more different types.

The (B) thermosetting resin is a reactive compound that can undergo crosslinking reaction by heat. As examples of such compounds there may be mentioned epoxy resins, cyanate resins, bismaleimide resins, phenol resins, urea resins, melamine resins, alkyd resins, acrylic resins, unsaturated polyester resins, diallyl phthalate resins, silicone resins, resorcinol-formaldehyde resins, xylene resins, furan resins, polyurethane resins, ketone resins, triallyl cyanurate resins, polyisocyanate resins, tris(2-hydroxyethyl)isocyanurate-containing resins, triallyl trimellitate-containing resins, thermosetting resins synthesized from cyclopentadienes, and thermosetting resins obtained by trimerization of aromatic dicyanamides.

Among these, epoxy resins, cyanate resins and bismaleimide resins are preferred from the viewpoint of imparting excellent adhesive force at high temperature, and epoxy resins are particularly preferred from the viewpoint of manageability and productivity. These (B) thermosetting resins may be used alone or in combinations of two or more.

The epoxy resin is more preferably one containing at least two epoxy groups in the molecule, and it is most preferably a phenol glycidyl ether-type epoxy resin from the viewpoint of curability and cured product properties. Examples of such resins include bisphenol A-type (or AD-type, S-type and F-type) glycidyl ethers, hydrogenated bisphenol A-type glycidyl ethers, ethylene oxide adduct bisphenol A-type glycidyl ethers, propylene oxide adduct bisphenol A-type glycidyl ethers, phenol-novolac resin glycidyl ethers, cresol-novolac resin glycidyl ethers, bisphenol A-novolac resin glycidyl ethers, naphthalene resin glycidyl ethers, trifunctional (or tetrafunctional) glycidyl ethers, dicyclopentadienephenol resin glycidyl ethers, dimer acid glycidyl esters, trifunctional (or tetrafunctional) glycidylamines, naphthalene resin glycidylamines, and the like. These may be used alone or in combinations of two or more types.

From the viewpoint of preventing electromigration and corrosion of metal conductor circuits, these epoxy resins are preferably high-purity products with a content of no greater than 300 ppm for impurity ions such as alkali metal ions, alkaline earth metal ions and halide ions, and particularly chloride ion or hydrolyzable chlorine.

The content of the (B) thermosetting resin is preferably 5-200 parts by weight and more preferably 10-100 parts by weight, based on 100 parts by weight as the total solid content of the adhesive. If the content is less than 5 parts by weight the heat resistance will tend to be reduced, and if it is greater than 200 parts by weight film formability will tend to be poor.

The (C) radiation-polymerizable compound is not particularly restricted so long as it is a compound that polymerizes and/or cures by exposure to radiation such as ultraviolet rays or an electron beam. As specific examples of radiation-polymerizable compounds there may be mentioned methyl acrylate, methyl methacrylate, ethyl acrylate, ethyl methacrylate, butyl acrylate, butyl methacrylate, 2-ethylhexyl acrylate, 2-ethylhexyl methacrylate, pentenyl acrylate, tetrahydrofurfuryl acrylate, tetrahydrofurfuryl methacrylate, diethyleneglycol diacrylate, triethyleneglycol diacrylate, tetraethyleneglycol diacrylate, diethyleneglycol dimethacrylate, triethyleneglycol dimethacrylate, tetraethyleneglycol dimethacrylate, trimethylolpropane diacrylate, trimethylolpropane triacrylate, trimethylolpropane dimethacrylate, trimethylolpropane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxypropane, 1,2-methacryloyloxy-2-hydroxypropane, methylenebisacrylamide, N,N-dimethylacrylamide, N-methylolacrylamide, triacrylates of tris(β-hydroxyethyl)isocyanurate, compounds represented by the following formula (XII), urethane acrylates, urethane methacrylates and urea acrylates.

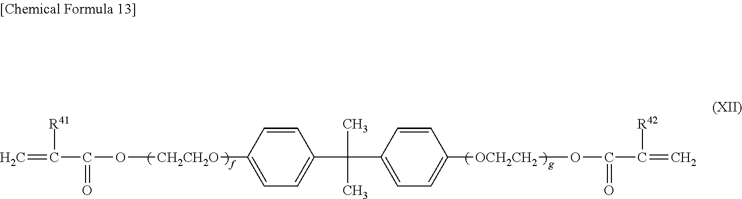

[In the formula, R⁴¹ and R⁴² each independently represent hydrogen or a methyl group, and f and g each independently represent an integer of 1 or greater.]

Urethane acrylates and urethane methacrylates are produced, for example, by reaction of diols, isocyanate compounds represented by the following formula (XIII) and compounds represented by the following formula (XIV).

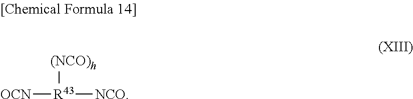

[In the formula, R⁴³ represents a C1-30 divalent or trivalent organic group, and h represents 0 or 1.]

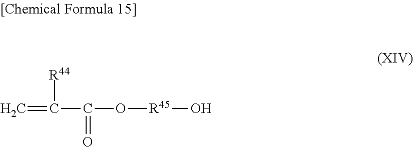

[In the formula, R⁴⁴ represents hydrogen or a methyl group, and R⁴⁵ represents an ethylene or propylene group.]

A urea methacrylate is produced, for example, by reaction of a diamine represented by the following formula (XV) and a compound represented by the following formula (XVI).

### [Chemical Formula 16]

H₂N—R⁴⁶—NH₂ (XV)

[In the formula, R⁴⁶ represents a C2-30 divalent organic group.]

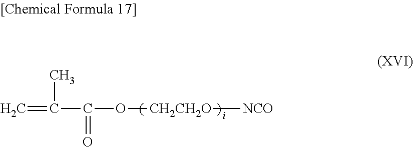

[In the formula, i represents 0 or 1.]

In addition to these compounds, there may be used radiation-polymerizable copolymers having ethylenic unsaturated groups on side chains, which are obtained by addition reaction of a compound having at least one ethylenic unsaturated group and a functional group such as an oxirane ring or an isocyanate, hydroxyl or carboxyl group, with a functional group-containing vinyl copolymer.

These radiation-polymerizable compounds may be used alone or in combinations of two or more. Among them, radiation-polymerizable compounds represented by formula (XII) above are preferred from the standpoint of imparting sufficient solvent resistance after curing, and urethane acrylates and urethane methacrylates are preferred from the standpoint of imparting sufficiently high adhesion after curing.

The content of the (C) radiation-polymerizable compound is preferably 20-200 parts by weight and more preferably 30-100 parts by weight with respect to 100 parts by weight of the (A) thermoplastic resin. A content of greater than 200 parts by weight will tend to lower the flow property during heat-fusion due to polymerization, thus reducing the adhesion during thermocompression bonding. On the other hand, a content of less than 20 parts by weight will tend to lower the solvent resistance after the photocuring by exposure, thus interfering with formation of the pattern.

A (D) photoinitiator is a photopolymerization initiator that generates free radicals by irradiation, or a photobase generator that generates a base by irradiation.

A photopolymerization initiator that generates free radicals by irradiation is preferably one having an absorption band of 300-500 nm, in order to obtain satisfactory sensitivity.

Specific examples of photopolymerization initiators include aromatic ketones such as benzophenone, N,N′-tetramethyl-4,4′-diaminobenzophenone (Michler's ketone), N,N-tetraethyl-4,4′-diaminobenzophenone, 4-methoxy-4′-dimethylaminobenzophenone, 2-benzyl-2-dimethylamino-1-(4-morpholinophenyl)-butanone-1,2,2-dimethoxy-1,2-diphenylethan-1-one, 1-hydroxy-cyclohexyl-phenyl-ketone, 2-methyl-1-(4-(methylthio)phenyl)-2-morpholinopropanone-1,2,4-diethylthioxanthone, 2-ethylanthraquinone and phenanthrenequinone, benzoinethers such as benzoinmethyl ether, benzoinethyl ether and benzoinphenyl ether, benzoins such as methylbenzoin and ethylbenzoin, benzyl derivatives such as benzyldimethylketal, 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-phenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer and 2-(2,4-dimethoxyphenyl)-4,5-diphenylimidazole dimer, acridine derivatives such as 9-phenylacridine and 1,7-bis(9,9′-acridinyl)heptane, and bisacylphosphine oxides such as bis(2,6-dimethoxybenzoyl)-2,4,4-trimethyl-pentylphosphine oxide and bis(2,4,6-trimethylbenzoyl)phenylphosphine oxide. These may be used alone or in combinations of two or more types.

The photobase generator may be any compound that generates a base upon irradiation, without any particular restrictions. Strongly basic compounds are preferred as bases to be generated, from the viewpoint of reactivity and curing speed. The pKa value, which is the logarithm of the acid dissociation constant, is generally used as the index of the basicity, and the pKa value is preferably 7 or greater and more preferably 9 or greater in aqueous solution.

Examples of bases generated by irradiation include imidazole and imidazole derivatives such as 2,4-dimethylimidazole and 1-methylimidazole, piperazine and piperazine derivatives such as 2,5-dimethylpiperazine, piperidine and piperidine derivatives such as 1,2-dimethylpiperidine, proline derivatives, trialkylamine derivatives such as trimethylamine, triethylamine and triethanolamine, pyridine derivatives with amino groups or alkylamino groups substituting at the 4-position, such as 4-methylaminopyridine or 4-dimethylaminopyridine, pyrrolidine and pyrrolidine derivatives such as n-methylpyrrolidine, alicyclic amine derivatives such as triethylenediamine and 1,8-diazabiscyclo(5,4,0)undecene-1 (DBU), and benzylamine derivatives such as benzylmethylamine, benzyldimethylamine and benzyldiethylamine.

As photobase generators that generate such bases by irradiation there may be used, for example, the quaternary ammonium salt derivatives described in Journal of Photopolymer Science and Technology Vol. 12, 313-314 (1999) and Chemistry of Materials Vol. 11, 170-176 (1999).

As photobase generators, there may be used the carbamic acid derivatives described in Journal of American Chemical Society Vol. 118 p. 12925(1996) and Polymer Journal Vol. 28 p. 795(1996).

There may also be used oxime derivatives that generate primary amino groups by irradiation of active light rays, and commercially available photoradical generators such as 2-methyl-1-(4-(methylthio)phenyl)-2-morpholinopropan-1-one (IRGACURE 907, product of Ciba Specialty Chemicals), 2-benzyl-2-dimethylamino-1-(4-morpholinophenyl)-butanone-1 (IRGACURE 369, product of Ciba Specialty Chemicals), hexaarylbisimidazole derivatives (with the halogen, alkoxy, nitro or cyano substituents optionally substituted with phenyl), and benzoisooxazolone derivatives.

In addition to, or instead of, using a photobase generator that generates a base by irradiation, the epoxy resin can be cured by generating a base by reaction such as photo Fries rearrangement, photo Claisen rearrangement, Curtius rearrangement, or Stevens rearrangement.

Since these compounds do not exhibit reactivity with the epoxy resin when not exposed to radiation at room temperature, they are characterized by having highly excellent storage stability at room temperature.

The content of the (D) photoinitiator is not particularly restricted, but for most purposes it may be 0.01-30 parts by weight with respect to 100 parts by weight of the (A) thermoplastic resin.

The photosensitive film adhesive may also contain a curing accelerator if necessary. The curing accelerator is not particularly restricted so long as it cures the (B) thermosetting resin, and as examples there may be mentioned imidazoles, dicyandiamide derivatives, dicarboxylic acid dihydrazides, triphenylphosphine, tetraphenylphosphoniumtetraphenyl borate, 2-ethyl-4-methylimidazoletetraphenyl borate and 1,8-diazabicyclo[5.4.0]undecene-7-tetraphenyl borate.

When an epoxy resin is used, a curing agent may be added to the photosensitive film adhesive if necessary. As examples of curing agents there may be mentioned phenol-based compounds, aliphatic amines, alicyclic amines, aromatic polyamines, polyamides, aliphatic acid anhydrides, alicyclic acid anhydrides, aromatic acid anhydrides, dicyandiamides, organic acid dihydrazides, boron trifluoride amine complexes, imidazoles, tertiary amines and the like. Phenol-based compounds are preferred among these, with phenol-based compounds having two or more phenolic hydroxyl groups in the molecule being more preferred.

As examples of such compounds there may be mentioned phenol-novolac, cresol-novolac, t-butylphenol-novolac, dicyclopentadiene cresol-novolac, dicyclopentadiene phenol-novolac, xylylene-modified phenol-novolac, naphthol-based compounds, trisphenol-based compounds, tetrakisphenol-novolac, bisphenol A-novolac, poly-p-vinylphenol, phenolaralkyl resins and the like. Compounds with number-average molecular weights in the range of 400-1500 are preferred among these. This will help minimize outgas during thermocompression bonding, that can cause contamination of the semiconductor element or apparatus.

The photosensitive film adhesive may also contain a filler. As fillers there may be used, for example, inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide and ceramics, and organic fillers such as carbon and rubber-based fillers, without any particular restrictions on the type or form.

The filler content may be set according to the properties or function to be imparted, but it will usually be 1-50 wt %, preferably 2-40 wt % and even more preferably 5-30 wt %, with respect to the total of the resin component and filler. Increasing the amount of filler can result in a high elastic modulus and effectively improve the dicing property (cuttability with a dicer blade), wire bonding property (ultrasonic efficiency) and hot bonding strength.

If the filler is increased above the necessary amount the thermocompression bonding property will tend to be impaired, and therefore the filler content is preferably limited to within the range specified above. The optimal filler content is determined for the desired balance of properties. In cases where a filler is used, mixing and kneading may be accomplished using an appropriate combination of dispersers such as an ordinary stirrer, kneader, triple roll, ball mill or the like.

The photosensitive film adhesive may contain a silane coupling agent or the like to improve the interfacial bonding between different types of materials, while an ion scavenger may also be added to adsorb ionic impurities and improve the wet insulating reliability. A thermal radical generator may further be added for reaction of the unreacted acrylate remaining during thermosetting.

The photosensitive film adhesive may be produced by dissolving the aforementioned components in an organic solvent such as dimethylformamide, toluene, benzene, xylene, methyl ethyl ketone, tetrahydrofuran, ethylcellosolve, ethylcellosolve acetate, dioxane, cyclohexanone, ethyl acetate or N-methyl-pyrrolidinone, for example, to prepare a varnish, and coating and drying it on a substrate such as release-treated PET.

The photosensitive film adhesive has both a function as a die bonding adhesive and a function as a photosensitive resin for formation of the patterned insulating resin film.

Embodiments of the semiconductor device and the method for producing a semiconductor device according to the invention include a semiconductor device having a semiconductor element-layered construction, a semiconductor device for a camera module, and a semiconductor device having a flip-chip structure. These embodiments will now be described, with the understanding that the invention is not limited thereto.

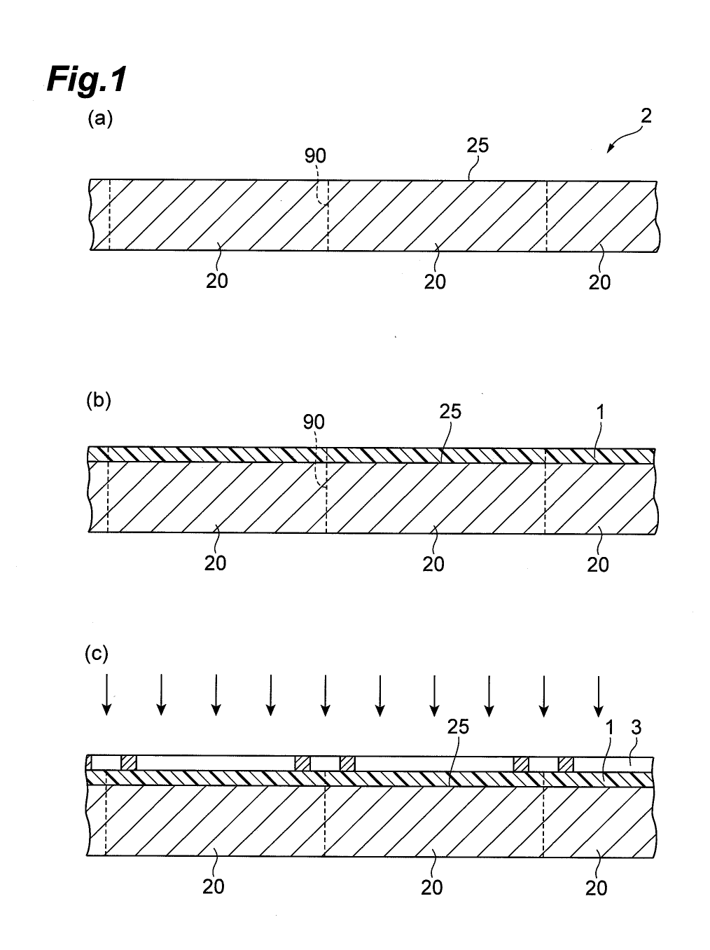

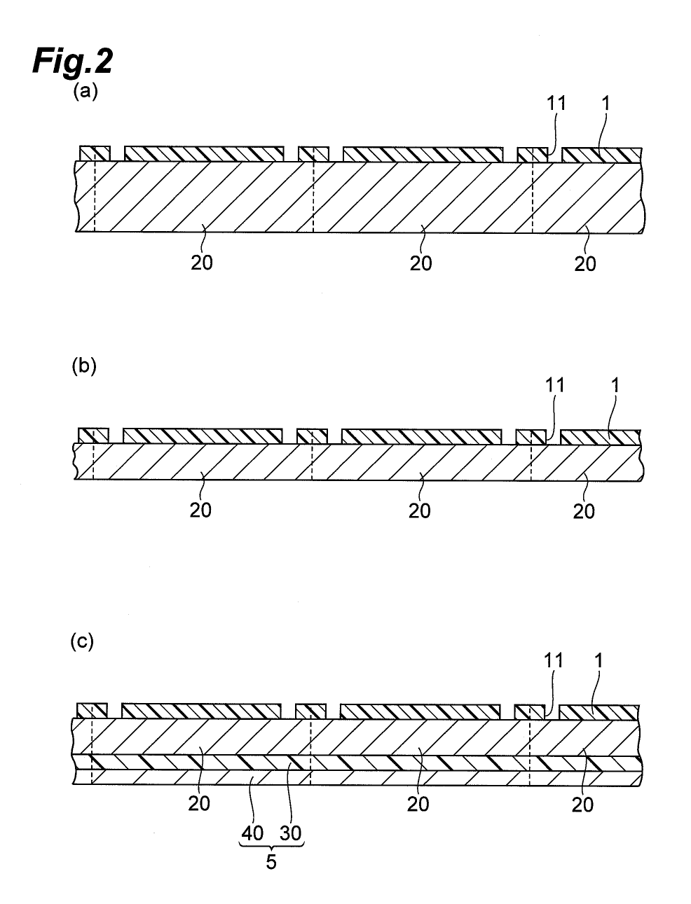

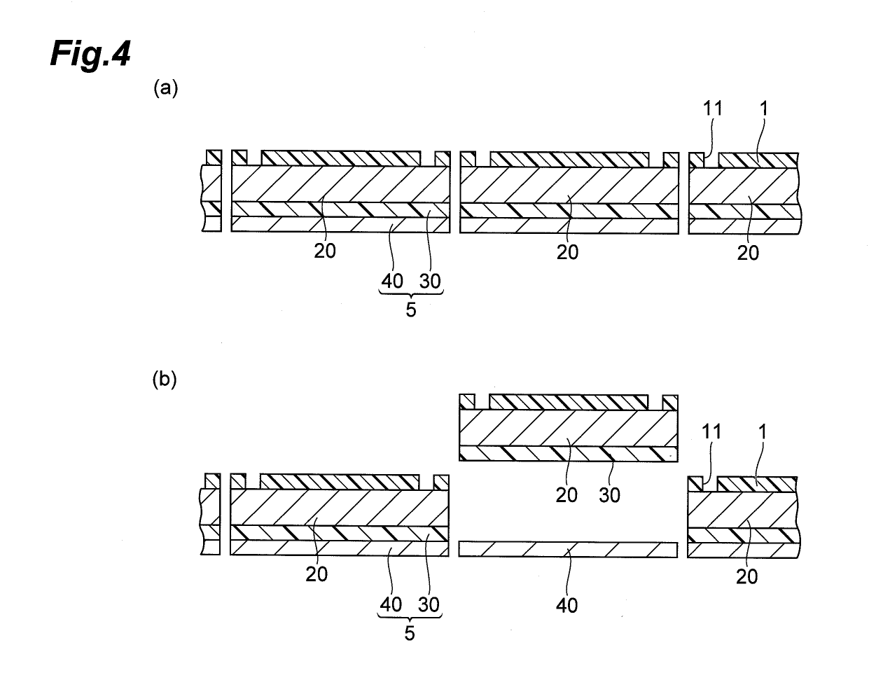

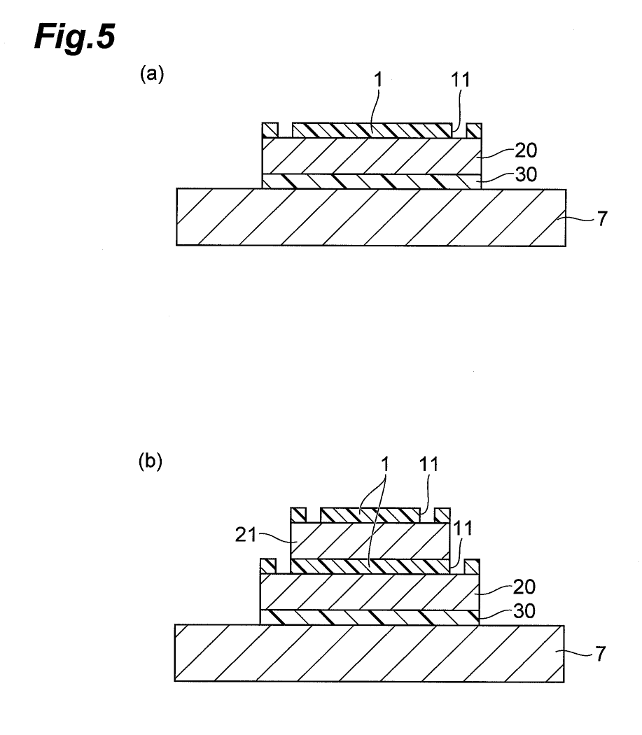

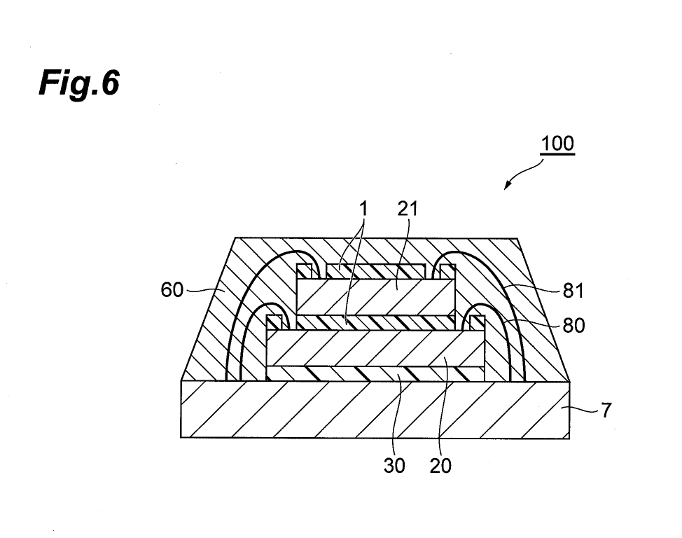

FIGS. 1, 2, 3, 4, 5 and 6 are end views or plan views of an embodiment of a method for producing a semiconductor device. The method for producing a semiconductor device according to this embodiment comprises a step of forming a film-like photosensitive adhesive 1 on a circuit side 25 of a semiconductor element 20 that has been formed on a semiconductor wafer 2 (FIG. 1(a), (b)), a step of patterning the film-like photosensitive adhesive 1 formed on the circuit side 25 of the semiconductor element 20 by exposure and development (FIG. 1(c), FIG. 2(a)), a step of polishing the semiconductor wafer 2 from the side opposite the circuit side 25 to reduce the thickness of the semiconductor wafer 2 (FIG. 2(b)), a step of cutting the semiconductor wafer 2 into multiple semiconductor elements 20 by dicing (FIG. 2(c), FIG. 4(a)), a step of picking up the semiconductor elements 20 and mounting them on a plate-like support substrate 7 for the semiconductor device (FIG. 4(b), FIG. 5(a)), a step of directly bonding a second semiconductor element 21 on the patterned photosensitive adhesive 1 on the circuit side of the semiconductor element 20 which has been mounted on the support substrate 7 (FIG. 5(b)), and a step of connecting each of the semiconductor elements 20,21 to external connecting terminals (FIG. 6).

In the semiconductor wafer 2 shown in FIG. 1(a) there are formed a plurality of semiconductor elements 20 partitioned by dicing lines 90. The film-like photosensitive adhesive 1 is provided on the circuit side 25 side of the semiconductor element 20 (FIG. 1(b)). A method of preparing the photosensitive adhesive 1 preformed into a film and attaching it onto the semiconductor wafer 2 is convenient.

The photosensitive adhesive 1 is a negative-type photosensitive adhesive capable of alkali development, that exhibits adhesion for the adherend after it has been patterned by light exposure and development. More specifically, the resist pattern formed by patterning of the film-like photosensitive adhesive 1 by light exposure and development exhibits adhesion for adherends. The resist pattern and the adherends can be bonded by, for example, contact bonding the adherends onto the resist pattern with heating if necessary. The adherend may be a semiconductor element, glass base material or the like. A semiconductor element as the adherend may have a patterned photosensitive film adhesive formed thereover.

The photosensitive adhesive 1 laminated on the semiconductor wafer 2 is irradiated with active light rays (typically ultraviolet rays) via a mask 3 having openings formed at prescribed locations (FIG. 1(c)). The photosensitive adhesive 1 is thus exposed to light in the prescribed pattern.

Following exposure, the sections of the photosensitive adhesive 1 that were not exposed to light are removed by development using an alkali developing solution, thus allowing the photosensitive adhesive 1 to be patterned in such a manner that openings 11 are formed (FIG. 2(a)). A positive photosensitive adhesive may be used instead of a negative one, in which case the sections of the photosensitive film adhesive exposed to light are removed by development.

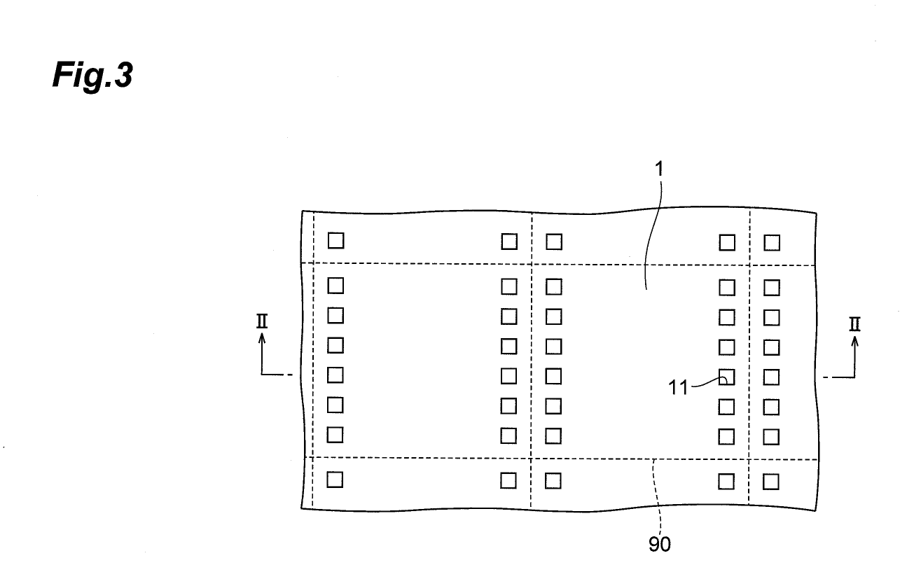

FIG. 3 is a plan view showing the patterned state of a photosensitive adhesive 1. The bonding pads of semiconductor elements 20 are exposed at the openings 11. That is, the patterned photosensitive adhesive 1 is the buffer coat film of the semiconductor elements 20. A plurality of rectangular openings 11 are formed in rows on each semiconductor element 20. The shapes, arrangement and number of openings 11 are not restricted to those of this embodiment, and they may be appropriately modified in such a manner that the prescribed sections of the bonding pads are exposed.

After patterning, the side of the semiconductor wafer 2 opposite the photosensitive adhesive 1 side may be polished to reduce the thickness of the semiconductor wafer 2 to the prescribed thickness (FIG. 2(b)). The polishing is carried out, for example, by attaching a pressure-sensitive adhesive film onto the photosensitive adhesive 1 and fixing the semiconductor wafer 2 on a polishing jig by the pressure-sensitive adhesive film. The step of reducing the semiconductor wafer thickness may also be carried out before patterning. When the semiconductor wafer thickness is reduced after patterning, the pressure-sensitive adhesive film may not be necessary.

After polishing, a composite film 5 comprising a die bonding film 30 and dicing film 40, laminated together, is attached to the side of the semiconductor wafer 2 opposite the photosensitive adhesive 1 side, oriented with the die bonding film 30 contacting the semiconductor wafer 2. The attachment may be carried out with heating if necessary.

Next, the semiconductor wafer 2 may be cut, together with the composite film 5, along the dicing lines 90 so that the semiconductor wafer 2 is partitioned into multiple semiconductor elements 20 (FIG. 4(a)). The dicing is accomplished using a dicing blade, for example, while the element is completely anchored to a frame by the dicing film 40.

After dicing, the semiconductor element 20 and the die bonding film 30 attached to its back side are both picked up (FIG. 4(b)). The picked up semiconductor element 20 may be mounted on a support substrate 7 via the die bonding film 30 (FIG. 5(a)).

A second semiconductor element 21 may then be directly bonded onto the photosensitive adhesive 1 of the semiconductor element 20 that has been mounted on the support substrate 7 (FIG. 5(b)). In other words, the semiconductor element 20 and the semiconductor element 21 positioned on its upper layer are bonded by the patterned photosensitive adhesive 1 (buffer coat film) lying between them. The semiconductor element 21 is bonded at a position such that the openings 11 of the patterned photosensitive adhesive 1 are not blocked. The patterned photosensitive adhesive 1 (buffer coat film) is preferably formed on the circuit side of the semiconductor element 21.

Bonding of the semiconductor element 21 may be accomplished by, for example, a method of thermocompression bonding while heating to a temperature at which the photosensitive adhesive 1 exhibits fluidity. Water content adjustment of the photosensitive film adhesive at this time can yield a heat-resistant semiconductor device. After thermocompression bonding, the photosensitive adhesive 1 may be heated if necessary to further promote curing.

Next, the semiconductor element 20 is connected to an external connecting terminal on the support substrate 7 via a wire 80 connected to its bonding pad, while the semiconductor element 21 is connected to an external connecting terminal on the support substrate 7 via a wire 81 connected to its bonding pad. The laminated body comprising the semiconductor elements may then be sealed with a sealing resin layer 60 to obtain a semiconductor device 100 (FIG. 6).

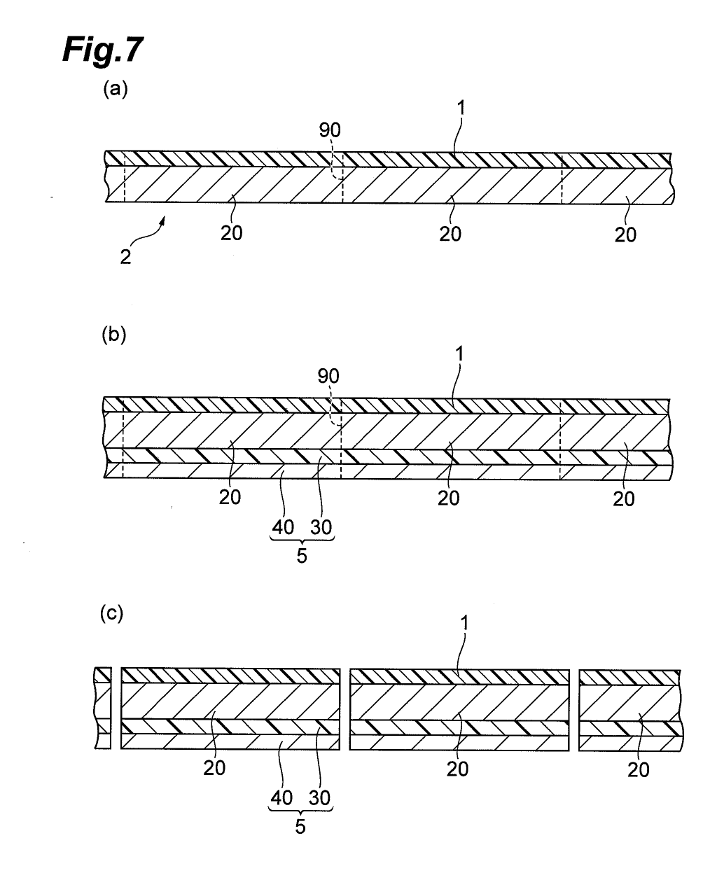

The method for producing a semiconductor device is not limited to the embodiments described above, and it may incorporate appropriate modifications that still fall within the gist of the invention. For example, the steps of adhesive film attachment, dicing, exposure and development and semiconductor wafer polishing may be carried out in a different order as appropriate. The semiconductor wafer 2 on which the film-like photosensitive adhesive 1 has been attached may also be thinned by polishing and then diced, as shown in FIG. 7. In this case, the photosensitive adhesive 1 is patterned by exposure and development after dicing, to obtain a laminated body similar to that shown in FIG. 4(a). Alternatively, the semiconductor wafer that has been thinned by polishing may be diced first, before attachment of the film-like photosensitive adhesive 1 and exposure and development thereof. Also, 3 or more semiconductor elements may be laminated, in which case at least one pair of adjacent semiconductor elements is preferably directly bonded by the patterned photosensitive adhesive (the buffer coat film on the lower layer side).

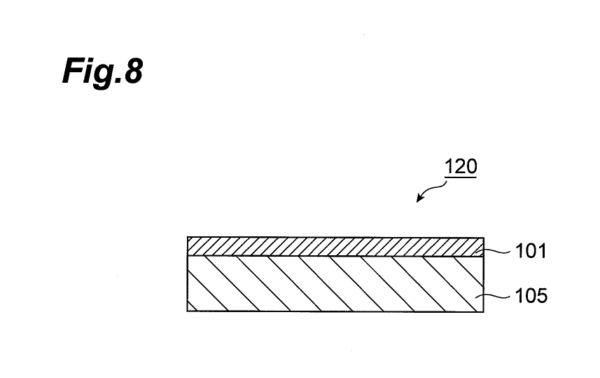

FIGS. 8 to 20 are cross-sectional views of an embodiment of a method for producing a semiconductor device. An adhesive layer-attached semiconductor wafer 120 is obtained by laminating an adhesive film (adhesive layer) 101 on a semiconductor wafer 105 while heating. The adhesive layer-attached semiconductor wafer 120 may be suitably used for production of electronic components such as CCD camera modules and CMOS camera modules, through a step of bonding an adherend to the semiconductor wafer 105 via the adhesive layer 101. An example of production of a CCD camera module will now be explained. A CMOS camera module can be produced by a similar method.

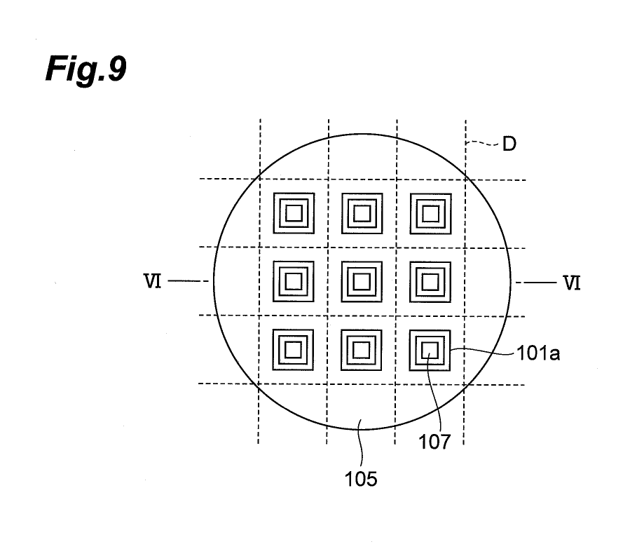

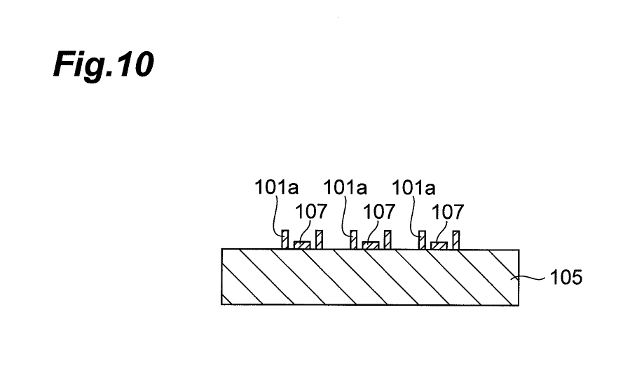

FIG. 9 is a top view showing an embodiment of an adhesive pattern, and FIG. 10 is an end view of FIG. 9 along line VI-VI. The adhesive pattern 101a shown in FIGS. 9 and 10 is formed on a semiconductor wafer 105 as the adherend, to provide a pattern which runs along the sides of approximate square shapes surrounding effective picture element regions 107 formed on the semiconductor wafer 105.

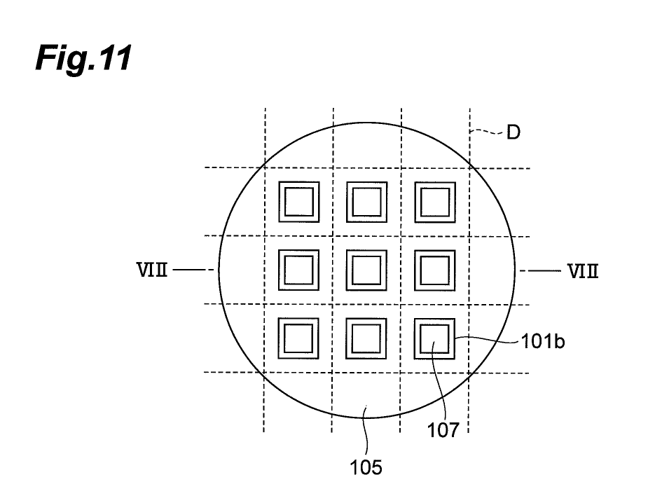

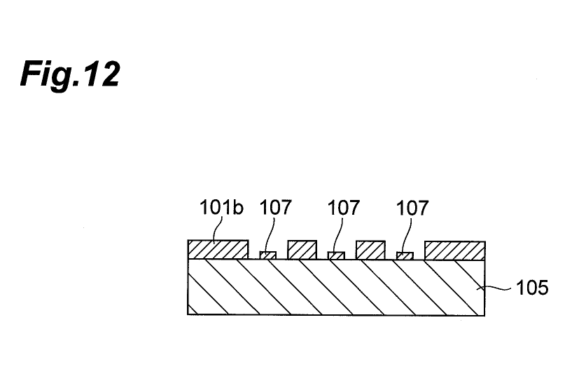

FIG. 11 is a top view showing an embodiment of an adhesive pattern, and FIG. 12 is an end view of FIG. 11 along line VIII-VIII. The adhesive pattern 101b shown in FIGS. 11 and 12 is patterned on a semiconductor wafer 105 as the adherend, in such a manner that approximately square openings are formed in which the effective picture element regions 107 on the semiconductor wafer 105 are exposed.

The adhesive patterns 101a and 101b are formed by forming the adhesive layer 101 composed of a photosensitive adhesive composition on the semiconductor wafer 105 as the adherend to obtain an adhesive layer-attached semiconductor wafer 120, exposing the adhesive layer 101 through a photomask, and developing the exposed adhesive layer 101 with an aqueous alkali solution. That is, the adhesive patterns 101a and 101b are composed of the exposed photosensitive adhesive composition.

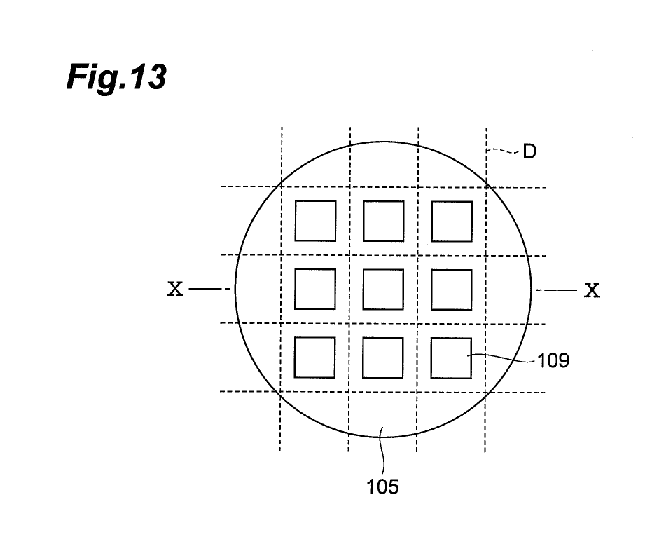

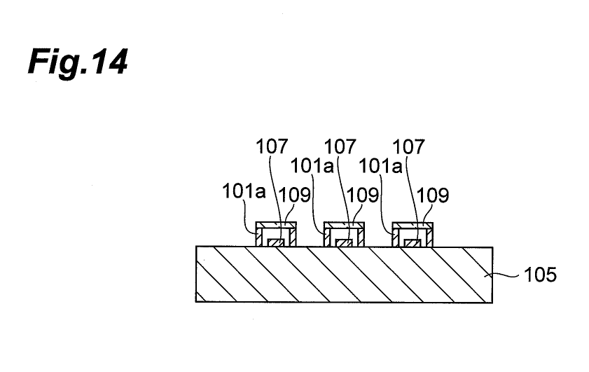

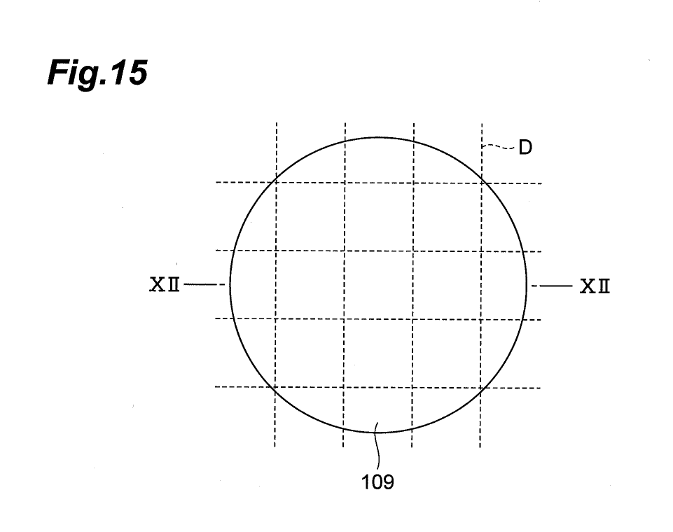

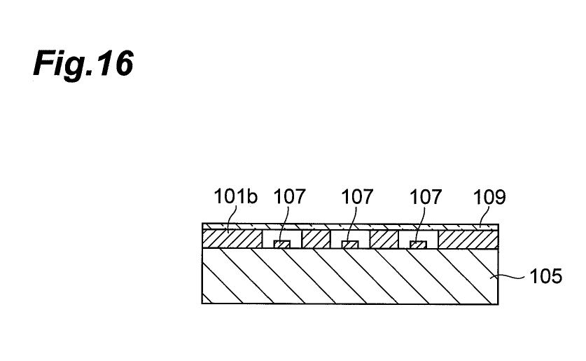

Next, a cover glass 109 is bonded as a separate adherend on the semiconductor wafer 120, via the adhesive pattern 101a or 101b. FIG. 13 is a top view showing the state of cover glass 109 bonded to a semiconductor wafer 120 through an adhesive pattern 101a, and FIG. 14 is an end view of FIG. 13 along line X-X. FIG. 15 is a top view showing the state of cover glass 109 bonded to a semiconductor wafer 120 through an adhesive pattern 101b, and FIG. 16 is an end view of FIG. 15 along line XI-XI. The cover glass 9 is bonded to the semiconductor wafer 120 while enveloping the heat-cured adhesive pattern 101a or 101b. The cover glass 109 is placed over the adhesive pattern 101a or 101b and thermocompression bonded thereto, so that the cover glass 109 is bonded. Water content adjustment of the photosensitive film adhesive at this time can prevent defects in the semiconductor device, such as peeling of the cover glass. The adhesive patterns 101a and 101b function as adhesives for bonding of the cover glass 109, while also functioning as spacers to guarantee space surrounding the effective picture element regions 107.

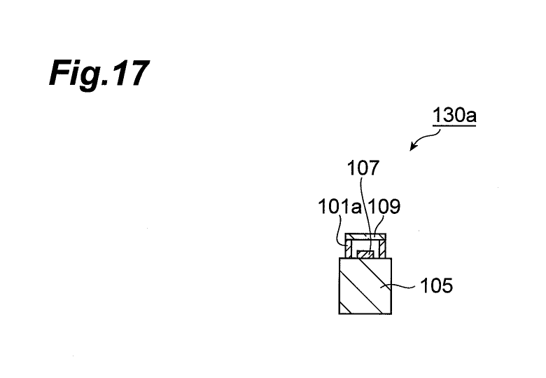

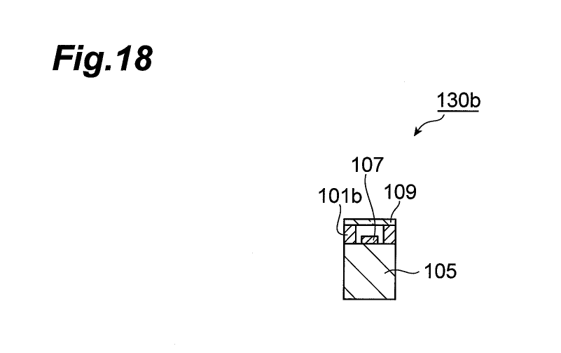

After the cover glass 109 has been bonded, it is diced along the dashed lines D to obtain the semiconductor device 130a shown in FIG. 17 or the semiconductor device 130b shown in FIG. 18. The semiconductor device 130a comprises a semiconductor wafer 105, an effective picture element region 107, an adhesive pattern (adhesive layer) 101a and a cover glass 109. The semiconductor device 130b comprises a semiconductor wafer 105, an effective picture element region 107, an adhesive pattern (adhesive layer) 101b and a cover glass 109.

The semiconductor device can be suitably used as an electronic component for a CCD camera module or the like.

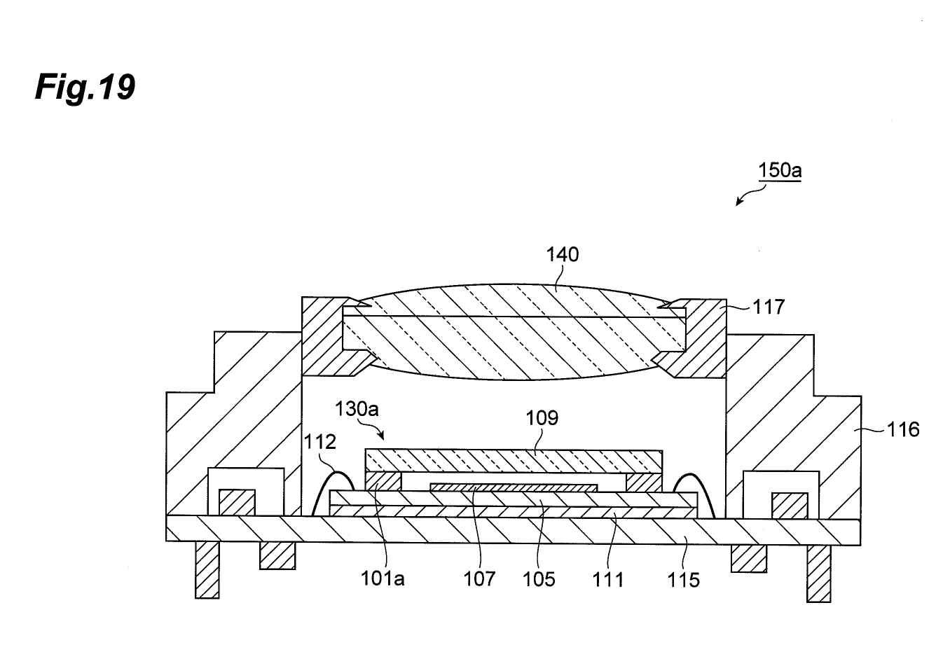

FIG. 19 is a cross-sectional view showing an embodiment of a CCD camera module comprising a semiconductor device as described above. The CCD camera module 150a shown in FIG. 19 is an electronic component comprising a semiconductor device 130a as a solid pickup element. The semiconductor device 130a is bonded to a semiconductor element-mounting support base 115 via a die bond film 111. The semiconductor device 130a is electrically connected with external connecting terminals via wires 112.

The CCD camera module 150a has a construction wherein a lens 140 provided at a location directly over the effective picture element region 107, side walls 116 provided so as to enclose the lens 140 and the semiconductor device 130a together with the lens 140, and a fitting member 117 lying between the lens 140 and side walls 116, in which the lens 140 is fitted, are mounted on the semiconductor element-mounting support base 115.

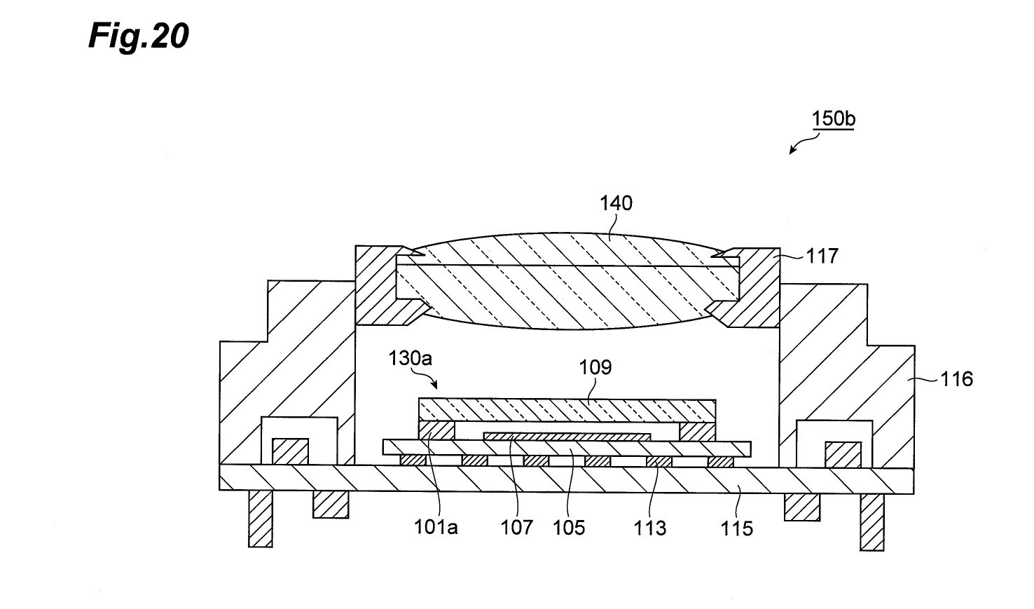

FIG. 20 is a cross-sectional view showing an embodiment of a CCD camera module, as an electronic component. The CCD camera module 150b shown in FIG. 19 has a construction wherein a semiconductor device 130a is bonded with a semiconductor element-mounting support base 115 via solder 113, instead of the construction wherein a die bonding film is used for bonding of the semiconductor device, as in the embodiment described above.

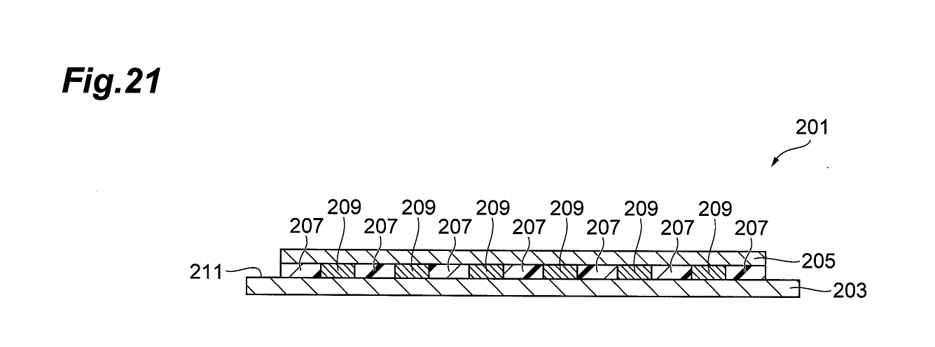

FIG. 21 is a cross-sectional view showing an embodiment of a semiconductor device. The semiconductor device 201 comprises a substrate with a connecting terminal (first connected section: not shown) (first adherend) 203, a semiconductor chip with a connecting electrode section (second connected section: not shown) (second adherend) 205, an insulating resin layer 207 made of a photosensitive adhesive and a conductive layer 209 made of a conductive material. The substrate 203 has a circuit side 211 opposing the semiconductor chip 205, and it is situated at a prescribed spacing from the semiconductor chip 205. The insulating resin layer 207 is formed between the substrate 203 and semiconductor chip 205 in contact with both the substrate 203 and semiconductor chip 205, and it has a prescribed pattern. The conductive layer 209 is formed between the substrate 203 and semiconductor chip 205 insulating resin layer at the sections where the insulating resin layer 207 is not present. The connecting electrode section of the semiconductor chip 205 is electrically connected to the connecting terminal of the substrate 203 via the conductive layer 209. The semiconductor device 201 may be suitably used as an electronic component comprising a flip-chip structure.

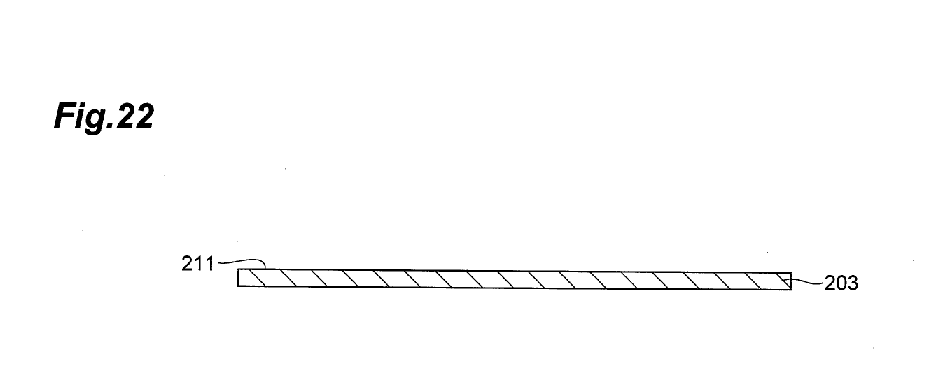

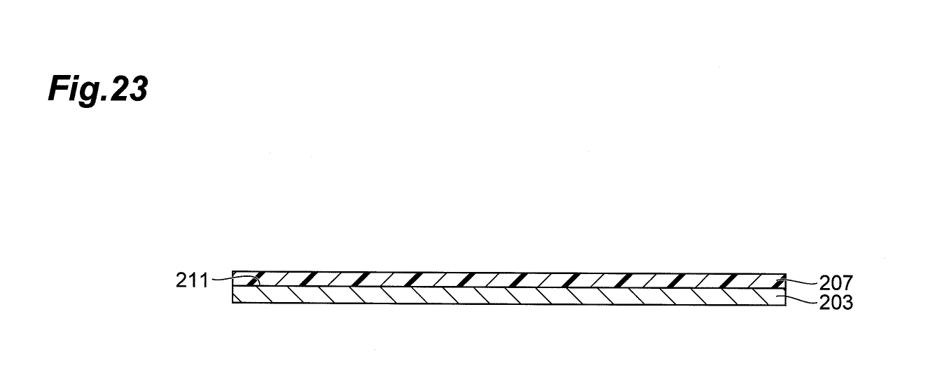

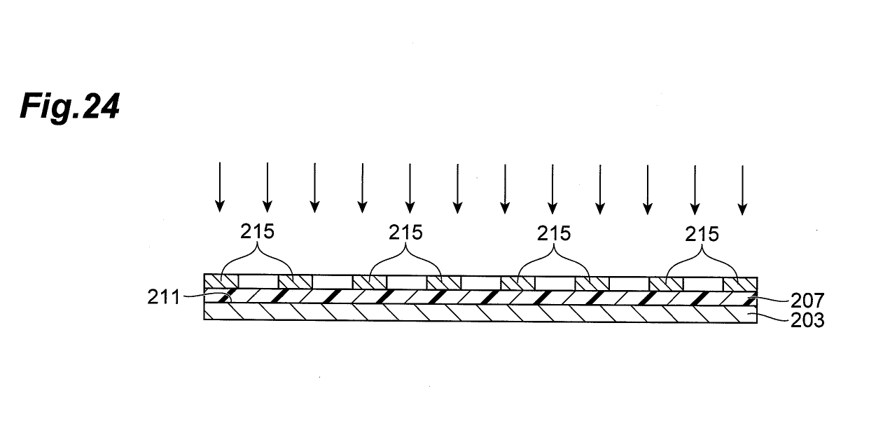

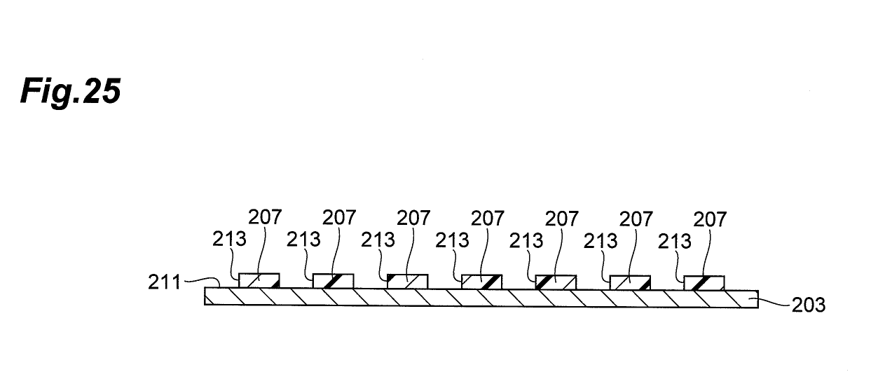

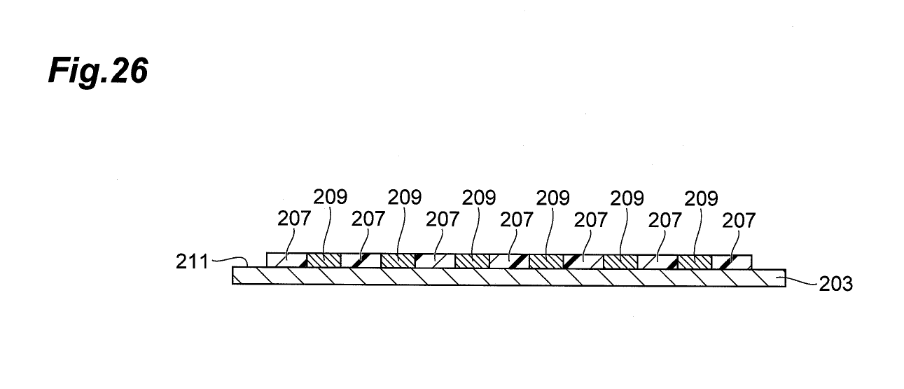

FIGS. 22 to 26 are cross-sectional views of an embodiment of a method for producing a semiconductor device. The method for producing a semiconductor device according to this embodiment comprises a step of forming an insulating resin layer 207 made of a photosensitive adhesive on a substrate 203 having a connecting terminal (first step: FIG. 22 and FIG. 23), a step of patterning the insulating resin layer 207 by light exposure and development so that openings 213 are formed where the connecting terminal is exposed (second step: FIG. 24 and FIG. 25), a step of filling a conductive material into the openings 213 to form a conductive layer 209 (third step: FIG. 26), and a step of directly bonding a semiconductor chip 205 having a connecting electrode section to the insulating resin layer 207 of the laminated body comprising the substrate 203 and insulating resin layer 207, while electrically connecting the connecting terminal of the substrate 203 to the connecting electrode section of the semiconductor chip 205 via the conductive layer 209 (fourth step).

The circuit side 211 of the substrate 203 shown in FIG. 22 is provided with an insulating resin layer 207 made of a photosensitive adhesive (FIG. 23). A method of preparing the photosensitive adhesive as a film (also referred hereunder as “adhesive film”) and attaching it onto the substrate 203 is convenient. The photosensitive adhesive may be formed by a method of coating a liquid varnish containing the photosensitive adhesive onto a substrate 203 by a spin coating method, and heating it to dryness.

The photosensitive adhesive is a negative-type photosensitive adhesive capable of alkali development, that exhibits adhesion for the adherend after it has been patterned by light exposure and development. More specifically, the resist pattern formed by patterning of the photosensitive adhesive by light exposure and development exhibits adhesion for adherends, such as the semiconductor chip and substrate. The resist pattern and the adherends can be bonded by, for example, contact bonding the adherends onto the resist pattern with heating if necessary. The details regarding a photosensitive adhesive with such a function will be explained below.

The insulating resin layer 207 formed on the substrate 203 is irradiated with active light rays (typically ultraviolet rays) through a mask 215 having openings formed at prescribed locations (FIG. 24). The insulating resin layer 207 is thus exposed to light in the prescribed pattern.

Following exposure, the sections of the insulating resin layer 207 that were not exposed to light are removed by development using an alkali developing solution, so that the insulating resin layer 207 is patterned in a manner such that openings 213 are formed where the connecting terminal of the substrate 203 is exposed (FIG. 25). A positive photosensitive adhesive may be used instead of a negative one, in which case the sections of the insulating resin layer 207 exposed to light are removed by development.

A conductive material is filled into the openings 213 of the obtained resist pattern to form a conductive layer 209 (FIG. 26). The method of filling the conductive material may be gravure printing, indenting with a roll, or pressure reduction filling. The conductive material used may be an electrode material made of a metal or metal oxide such as solder, gold, silver, nickel, copper, platinum, palladium or ruthenium oxide, and it may consist of bumps of such metals or, for example, it may comprise at least conductive particles and a resin component. The conductive particles may be, for example, conductive particles made of a metal or metal oxide of gold, silver, nickel, copper, platinum, palladium or ruthenium oxide, or an organometallic compound. As resin components there may be used a curable resin composition comprising an epoxy resin and its curing agent, for example.

The semiconductor chip 205 is directly bonded to the insulating resin layer 207 on the substrate 203. The connecting electrode section of the semiconductor chip 205 is electrically connected to the connecting terminal of the substrate 203 via the conductive layer 209. A patterned insulating resin layer (buffer coat film) may be formed on the circuit side of the semiconductor chip 205 opposite the insulating resin layer 207 side.

Bonding of the semiconductor chip 205 is accomplished by, for example, a method of thermocompression bonding while heating to a temperature at which the photosensitive adhesive exhibits fluidity. Water content adjustment of the photosensitive film adhesive at this time can yield a heat-resistant semiconductor device. After thermocompression bonding, the insulating resin layer 207 is heated if necessary to further promote curing.

A back side protective film is preferably attached to the circuit side (back side) of the semiconductor chip 205 opposite the insulating resin layer 207 side.

A semiconductor device 201 having the construction shown in FIG. 21 is thus obtained. The method for producing a semiconductor device is not limited to the embodiments described above, and it may incorporate appropriate modifications that still fall within the gist of the invention.

For example, the photosensitive adhesive is not limited to being formed first on the substrate 203, and may instead be formed first on the semiconductor chip 205. In this case, the method for producing a semiconductor device comprises, for example, a first step of forming an insulating resin layer 207 made of a photosensitive adhesive on a semiconductor chip 205 having a connecting electrode section, a second step of patterning the insulating resin layer 207 by light exposure and development so that openings 213 are formed where the connecting electrode section is exposed, a third step of filling the conductive material into the openings 213 to form a conductive layer 209, and a fourth step of directly bonding a substrate 203 having a connecting terminal to the insulating resin layer 207 of the laminated body comprising the semiconductor chip 205 and insulating resin layer 207, while electrically connecting the connecting terminal of the substrate 203 to the connecting electrode section of the semiconductor chip 205 via the conductive layer 209.

In this production method, connection is between the individuated substrate 203 and semiconductor chip 205, and it is therefore preferred from the viewpoint of facilitating connection between the connecting terminal on the substrate 203 and the connecting electrode section on the semiconductor chip 205.

The photosensitive adhesive may also be formed first on a semiconductor wafer composed of a plurality of semiconductor chips 205. In this case, the method for producing a semiconductor device comprises, for example, a first step of forming an insulating resin layer 207 made of a photosensitive adhesive on a semiconductor wafer 217 composed of a plurality of semiconductor chips 205 with connecting electrode sections (FIG. 7), a second step of patterning the insulating resin layer 207 by light exposure and development so that openings 213 are formed where the connecting electrode section is exposed, a third step of filling the openings 213 with a conductive material to form a conductive layer 209, a fourth step of directly bonding a wafer-size substrate having a connecting terminal (a substrate having approximately the same size as a semiconductor wafer) 203 onto the insulating resin layer 207 of the laminate body comprising the semiconductor wafer 217 and insulating resin layer 207, while electrically connecting the connecting terminal of the substrate 203 and the connecting electrode sections of the semiconductor chips 205 composing the semiconductor wafer 217, via the conductive layer 209, and a fifth step of dicing the laminate body of the semiconductor wafer 217, insulating resin layer 207 and substrate 203 into semiconductor chips 205.

In this production method, an insulating resin layer 207 made of a photosensitive adhesive is provided on a wafer-size substrate 203 in the first step, a semiconductor wafer 217 is directly bonded to the insulating resin layer 207 of the laminated body comprising the substrate 203 and insulating resin layer 207 while electrically connecting the connecting terminal of the substrate 203 with the connecting electrode sections of the semiconductor chips 205 composing the semiconductor wafer 217 via the conductive layer 209 in the fourth step, and the laminated body comprising the semiconductor wafer 217, insulating resin layer 207 and substrate 203 is diced into semiconductor chips 205 in the fifth step.

The step up to connection of the semiconductor wafer 217 and substrate 203 (fourth step) in this production method are preferred from the viewpoint of working efficiency because they can be carried out with a wafer size. A back side protective film is preferably attached to the circuit side (back side) of the semiconductor wafer 217 opposite the insulating resin layer 207 side.

Another method for producing a semiconductor device comprises a first step of forming an insulating resin layer 207 made of a photosensitive adhesive on a semiconductor wafer 217 composed of a plurality of semiconductor chips 205 having connecting electrode sections, a second step of patterning the insulating resin layer 207 by light exposure and development so that openings 213 are formed where the connecting electrode sections are exposed, a third step of filling the conductive material into the openings 213 to form a conductive layer 209, a fourth step of dicing the laminated body comprising the semiconductor wafer 217 and insulating resin layer 207 into semiconductor chips 205, and a fifth step of directly bonding a substrate 203 having a connecting terminal to the insulating resin layer 207 of the laminated body comprising the individuated semiconductor chips 205 and insulating resin layer 207, while electrically connecting the connecting terminal of the substrate 203 to the connecting electrode sections of the semiconductor chips 205 via the conductive layer 209.

In this production method, an insulating resin layer 207 made of a photosensitive adhesive may be provided on a wafer-size substrate 203 in the first step, the laminate body comprising the wafer-size substrate 203 and insulating resin layer 207 may be diced into semiconductor chips 205 in the fourth step, and the semiconductor chips 205 may be directly bonded to the insulating resin layer 207 of the laminate body comprising the individuated substrate 203 and insulating resin layer 207 while electrically connecting the connecting terminal of the substrate 203 with the connecting electrode sections of the semiconductor chips 205 via the conductive layer 209, in the fifth step.

This production method is preferred in that the steps from formation of the photosensitive adhesive to filling of the conductive material (third step) are carried out with a wafer size, and the dicing step (fourth step) can be accomplished smoothly.

The photosensitive adhesive may be used to bond together semiconductor wafers or semiconductor chips to form a semiconductor laminated body. Through electrodes may also be formed in the laminated body.

In this case, the method for producing a semiconductor device comprises, for example, a first step of forming an insulating resin layer 207 made of a photosensitive adhesive on a first semiconductor chip 205 having a through electrode-connecting electrode section, a second step of patterning the insulating resin layer 207 by light exposure and development so that openings 213 are formed where the connecting electrode section is exposed, a third step of filling the conductive material into the openings 213 to form through electrode connections, and a fourth step of directly bonding a second semiconductor chip 205 having a connecting electrode section to the insulating resin layer 207 of the laminated body comprising the first semiconductor chip 205 and insulating resin layer 207, while electrically connecting together the connecting electrode sections of the first and second semiconductor chips 205 via a conductive layer 209. A semiconductor wafer may be used instead of a semiconductor chip in this production method.

The electronic component described above is produced by a common curing step for adhesive curing, and a solder reflow step.

### EXAMPLES

The present invention will now be explained in greater detail based on examples and comparative examples, with the understanding that the invention is in no way limited to the examples.

### (Synthesis of Polyimide PI-1)

In a flask equipped with a stirrer, thermometer and nitrogen substitution device there were charged 3.43 g of 5,5′-methylene-bis(anthranilic acid) (molecular weight: 286.3, hereunder referred to as “MBAA”), 31.6 g of an aliphatic etherdiamine (“D-400”, trade name of BASF, molecular weight: 452.4), 2.48 g of 1,1,3,3-tetramethyl-1,3-bis(4-aminophenyl)disiloxane (“BY16-871EG”, trade name of Toray/Dow Corning Silicone, molecular weight: 248.5) and 105 g of N-methyl-2-pyrrolidinone (hereunder referred to as “NMP”).

Next, 32.6 g of 4,4′-oxydiphthalic dianhydride (molecular weight: 326.3, hereunder referred to as “ODPA”) was added to the flask in small portions at a time while cooling the flask in an ice bath. Upon completion of the addition, the mixture was further stirred at room temperature for 5 hours.

A water receptor-equipped reflux condenser was then mounted on the flask, 70 g of xylene was added, the temperature was increased to 180° C. while blowing in nitrogen gas to maintain the temperature for 5 hours, and the xylene was azeotropically removed with the water. A polyimide (hereunder, “polyimide PI-1”) was thus obtained.

The weight-average molecular weight (Mw) of the obtained polyimide PI-1 was measured by GPC to be Mw=31,000 based on polystyrene.

The Tg of the obtained polyimide PI-1 was 55° C.

(Synthesis of polyimide PI-2)

In a flask equipped with a stirrer, thermometer and nitrogen substitution device there were charged 2.86 g of MBAA, 14.0 g of D-400, 2.48 g of BY16-871EG, 8.17 g of etherdiamine (“B-12”, trade name of BASF, molecular weight: 204.3) and 110 g of NMP.

Next, 32.6 g of ODPA was added to the flask in small portions at a time while cooling the flask in an ice bath. Upon completion of the addition, the mixture was further stirred at room temperature for 5 hours.

A water receptor-equipped reflux condenser was then mounted on the flask, 73 g of xylene was added, the temperature was increased to 180° C. while blowing in nitrogen gas to maintain the temperature for 5 hours, and the xylene was azeotropically removed with the water. A polyimide (hereunder, “polyimide PI-2”) was thus obtained.

The weight-average molecular weight (Mw) of the obtained polyimide PI-2 was measured by GPC to be Mw=28,000 based on polystyrene.

The Tg of the obtained polyimide PI-2 was 60° C.

(Synthesis of polyimide PI-3)

In a flask equipped with a stirrer, thermometer and nitrogen substitution device there were charged 14.65 g of 2,2-bis(3-amino-4-hydroxyphenyl)hexafluoropropane (molecular weight: 366.26, hereunder referred to as “BIS-AP-AF”), 18.09 g of an aliphatic etherdiamine (“D-400”, trade name of BASF, molecular weight: 452.4), 2.48 g of 1,1,3,3-tetramethyl-1,3-bis(4-aminophenyl)disiloxane (“BY16-871EG”, trade name of Toray/Dow Corning Silicone, molecular weight: 248.5) and 105 g of N-methyl-2-pyrrolidinone (hereunder referred to as “NMP”).

Next, 32.6 g of 4,4′-oxydiphthalic dianhydride (molecular weight: 326.3, hereunder referred to as “ODPA”) was added to the flask in small portions at a time while cooling the flask in an ice bath. Upon completion of the addition, the mixture was further stirred at room temperature for 5 hours.

A water receptor-equipped reflux condenser was then mounted on the flask, 70 g of xylene was added, the temperature was increased to 180° C. while blowing in nitrogen gas to maintain the temperature for 5 hours, and the xylene was azeotropically removed with the water. A polyimide (hereunder, “polyimide PI-3”) was thus obtained.

The weight-average molecular weight (Mw) of the obtained polyimide PI-3 was measured by GPC to be Mw=33,000 based on polystyrene.

The Tg of the obtained polyimide PI-3 was 75° C.

(Synthesis of Polyimide PI-4)

In a 300 mL flask equipped with a thermometer, stirrer, condenser tube and nitrogen inflow tube there was stirred a reaction mixture containing 27.1 g (0.06 mol) of D-400, 2.48 g (0.01 mol) of BY16-871EG, 8.58 g (0.03 mol) of MBAA and 113 g of N-methyl-2-pyrrolidone (NMP). After the diamine dissolved, 32.62 g (0.1 mol) of ODPA and 5.76 g (0.03 mol) of trimellitic anhydride (molecular weight: ≦192.1, hereunder abbreviated as TAA) were added in small portions at a time. This was stirred for 8 hours at room temperature, and then 75.5 g of xylene was added and the mixture was heated at 180° C. while blowing in nitrogen gas to azeotropically remove the xylene with water to obtain a polyimide resin (PI-4) varnish.

The weight-average molecular weight Mw of the obtained polyimide PI-4 was measured by GPC to be 25,000 based on polystyrene. The Tg of the obtained polyimide PI-4 was 70° C.

(Preparation of Varnish)

Polyimides, radiation-polymerizable compounds, photopolymerization initiators, epoxy resins, curing agents, fillers and coating solvents were combined in the mixing proportions listed in Tables 1 and 2 to prepare varnishes F-01 to F-05.

TABLE 1

| | | | F-01 | F-02 | F-03 |
|---|---|---|---|---|---|
| Polyimide (100 pts. by wt.) | | | PI-1 | PI-1 | PI-2 |
| Film | Radiation-polymerizable | BPE-100 | 40 | | |
| composition | compound | U-2PPA | 40 | 40 | 40 |
| | | M-313 | | 40 | 40 |
| | Photo polymerization | I-819 | 3 | 1 | 2 |
| | initiator | I-OXE02 | | 0.5 | 1 |
| | Epoxy resin | VG-3101 | 5 | 5 | 5 |
| | | YDF-8170 | 10 | 10 | 10 |
| | Curing agent | TrisP-PA | 5 | 5 | 5 |
| | Filler | R972 | 5 | 10 | 10 |
| | Coating solvent | NMP | 200 | 200 | 200 |

TABLE 2

| | F-04 | F-05 |
|---|---|---|
| Polyimide (100 pts. by wt.) | PI-3 | PI-4 |

| | | | |
|---|---|---|---|
| Radiation- | BPE-100 | | 40 |
| polymerizable | M-313 | 80 | 30 |
| compound | | | |
| Epoxy resin | YDF-8170 | 30 | 15 |
| | EA-1010NT | 20 | 20 |
| Curing agent | TrisP-PA | 20 | 10 |
| Filler | R972 | 5 | 10 |
| Photo | I-819 | 2 | 2 |
| polymerization | I-OXE02 | 1 | 1 |
| initiator | | | |
| Heat radical | PERCUMYL D | 1 | 2 |
| generator | | | |
| Coating solvent | NMP | 200 | 200 |

The abbreviations for the components in Tables 1 and 2 have the following meanings.

BPE-100: Ethoxylated bisphenol A dimethacrylate by Shin-Nakamura Chemical Corp.

U-2PPA: Urethane acrylate by Shin-Nakamura Chemical Corp.

M-313: Isocyanuric acid/EO-modified di- and triacrylate by Toagosei Co., Ltd.

I-819: bis(2,4,6-Trimethylbenzoyl)-phenylphosphine oxide by Ciba Specialty Chemicals Co., Ltd.

I-OXE02: Ethanone, 1-[9-ethyl-6-(2-methylbenzoyl)-9H-carbazol-3-yl]-1-(O-acetyloxime), oxime ester group-containing compound, by Ciba Specialty Chemicals Co., Ltd.

VG3101: Trifunctional epoxy resin by Printec.

YDF-8170: Bisphenol F-type epoxy resin by Tohto Kasei Co., Ltd.

TrisP-PA: Trisphenol compound (a,a,a′-tris(4-hydroxyphenyl)-1-ethyl-4-isopropylbenzene) by Honshu Chemical Industry Co., Ltd.

R972: Hydrophobic fumed silica (mean particle size: approximately 16 nm) by Nippon Aerosil Co., Ltd.

PERCUMYL D: Dicumyl peroxide by NOF Corp. (1 minute half-life temperature: 175° C.).

EA-1010NT: bis A-type acryl-modified monofunctional epoxy resin by Shin-Nakamura Chemical Corp.

NMP: N-methyl-2-pyrrolidinone by Kanto Kagaku Co., Ltd.

### Examples 1-7 and Comparative Examples 1-3

Each of the obtained varnishes was coated onto a substrate (release-treated PET film) to a thickness of 50 μm, and heated in an oven at 80° C. for 30 minutes and then at 120° C. for 30 minutes to obtain a substrate-attached film adhesive.

The properties of the film adhesives of Examples 1-7 and Comparative Examples 1-3 were evaluated under the conditions described below. The results are shown in Tables 3 to 5.

An adhesive sheet, comprising a photosensitive film adhesive with a thickness of 50 μm formed on a transparent PET substrate, with a transparent PET film additionally attached as a cover film, was cut to a size of 150 mm×150 mm. A mask was placed over the cut adhesive sheet, and a high-precision parallel exposure apparatus (product of Orc Manufacturing Co., Ltd.) was used for exposure (ultraviolet irradiation) under conditions with an exposure dose of 1000 mJ/cm², followed by heating at 80° C. for 30 seconds. Next, the PET film was released from one side and a spray developer by Yako Co., Ltd. was used for development (developing solution: 2.38% tetramethylammonium hydride (TMAH), 27° C., 0.18 MPa spray pressure; washing: purified water, 23° C., 0.02 MPa spray pressure).

A pattern was formed on the other side of the PET substrate, and then the TMAH adhering to the film was washed off with purified water for 6 minutes. This was allowed to stand at room temperature for 30 minutes, the PET substrate was released, and an AQV2100CT water measuring apparatus by Hiranuma Sangyo Corp. was used to measure the water content of the patterned photosensitive film adhesive.

When heat treatment was carried out as water content adjustment after patterning, the obtained sample was placed on polyethylene fluoride-based fiber sheets or the like, and the polyethylene fluoride-based fiber sheets placed on a hot plate and heated with prescribed temperature and time conditions.

(Thermal History Stability After Thermocompression Bonding)

A laminator was used to laminate the substrate-attached photosensitive film adhesive onto a silicon wafer with a 6-inch diameter and a 400 μm thickness, under conditions with a laminating temperature of 80° C., a linear pressure of 4 kgf/cm and a feed rate of 0.5 m/min.

Next, a negative pattern mask was placed on the PET substrate side of the substrate-attached photosensitive film adhesive, and a high-precision parallel exposure apparatus (EXM-1172-B-∞, product of Orc Manufacturing Co., Ltd.) was used for exposure (ultraviolet irradiation) under conditions with an exposure dose of 1000 mJ/cm², followed by heating under conditions of 80° C. for 30 seconds. The substrate was then released, and a conveyor developing machine (Yako Co., Ltd.) was used for spray development (developing solution: 2.38% tetramethylammonium hydride (TMAH), 27° C., spray pressure: 0.18 MPa, washing: purified water, 23° C., spray pressure: 0.02 MPa) for patterning of the photosensitive film adhesive.

After development, the adhering TMAH was washed off with purified water for 6 minutes and the adhesive was allowed to stand at room temperature for 30 minutes, after which the standing period was extended or water absorption treatment was carried out, as necessary, and the patterning was followed by water content adjustment under prescribed conditions.

Immediately after the heat drying, a 30 mm×30 mm×0.35 mm thickness glass was placed on the patterned photosensitive film adhesive, and an OH-105ATF flat-tool thermocompression bonding apparatus by Ohashi Engineering was used for thermocompression bonding under conditions with a contact bonding temperature of 150° C., a contact bonding load of 0.5 MPa and a contact bonding time of 10 minutes.

The obtained sample was heat cured in an oven at 160° C. for 3 hours and at 180° C. for 3 hours. It was then heated on a hot plate at 260° C., and the time until glass/adhesive interfacial peeling or generation of voids due to foaming was measured. An evaluation of “NG” was assigned when peeling or foaming occurred immediately after heating at 260° C.

TABLE 3

| | Example 1 | Example 2 | Example 3 | Example 4 | Example 5 |
|---|---|---|---|---|---|
| Film | F-01 | F-02 | F-03 | F-01 | F-01 |
| Standing | None | None | None | 160° C./ | 160° C./ |
| conditions or | | | | 10 min + | 10 min + |
| moisture | | | | room | 30° C./ |
| absorption | | | | temp. 24 h | 90% |
| conditions | | | | | RH24 h |
| after | | | | | |
| development | | | | | |
| Post- | 160° C./ | 200° C./ | 180° C./ | 120° C./ | 120° C./ |
| patterning | 10 min | 1 min | 3 min | 3 min | 3 min |
| water | | | | | |
| content | | | | | |
| control | | | | | |
| treatment | | | | | |
| conditions | | | | | |
| Water | 0.5 | 0.3 | 0.4 | 0.6 | 0.5 |
| content | | | | | |
| (wt %) | | | | | |
| Heat history | 300 sec | >1000 sec | >1000 sec | 300 sec | 300 sec |
| stability after | | | | | |
| thermal | | | | | |
| compression | | | | | |

TABLE 4

| | Example 6 | Example 7 |
|---|---|---|
| Film | F-04 | F-05 |
| Standing conditions or | Room temp. | Room temp. |
| moisture absorption | 24 h | 24 h |
| conditions after | | |
| development | | |
| Post-patterning water | 160° C./10 min | 160° C./10 min |
| content control treatment | | |
| conditions | | |
| Water content (wt %) | 0.2 | 0.6 |
| Heat history stability after | >1000 | >1000 |
| thermal compression | | |

TABLE 5

| | Comp. Ex. 1 | Comp. Ex. 2 | Comp. Ex. 3 |
|---|---|---|---|
| Film | F-01 | F-02 | F-03 |
| Standing conditions or | None | 160° C./ | 160° C./ |
| moisture absorption | | 10 min + | 10 min + |
| conditions after | | room | 30° C./90% |
| development | | temp. 24 h | RH24 h |
| Post-patterning water | None | None | None |
| content control treatment | | | |
| conditions | | | |
| Water content (wt %) | 1.2 | 1.1 | 1.1 |
| Heat history stability after | NG | NG | NG |
| thermal compression | | | |

As clearly seen from Tables 3 to 5, the adhesives of Examples 1-7 had excellent thermal history stability (heat resistance) following thermocompression bonding, compared to those of Comparative Examples 1-3.

### Explanation of Symbols

1: Film-like photosensitive adhesive (adhesive film), 2: semiconductor wafer, 3, 215: masks, 5: composite film, 7: support substrate, 9: cover glass, 11: opening, 20, 21: semiconductor elements, 25: circuit side, 30: die bonding film, 40: dicing film, 60: sealing resin layer, 80, 81: wires, 90: dicing line, 100, 130a, 130b, 201: semiconductor devices, 101: adhesive layer, 101a: adhesive pattern, 101b: adhesive pattern, 107: effective picture element region, 109: cover glass, 111: die bond film, 112: wire, 115: semiconductor element-mounting support base, 116: side wall, 117: fitting member, 120: adhesive layer-attached semiconductor wafer, 140: lens, 150a, 150b: CCD camera modules, 203: substrate, 205: semiconductor chip, 207: insulating resin layer, 209: conductive layer, 211: circuit side, 213: opening, 217: semiconductor wafer.

1. A semiconductor device comprising a semiconductor element and an adherend thermocompression bonded via a patterned photosensitive film adhesive,
wherein the water content of the patterned photosensitive film adhesive just before thermocompression bonding is no greater than 1.0 wt %.

2. The semiconductor device according to claim 1, wherein the adherend is a semiconductor element or protective glass.

3. The semiconductor device according to claim 1, wherein the photosensitive film adhesive comprises at least a (A) thermoplastic resin and a (B) thermosetting resin.

4. The semiconductor device according to claim 3, wherein the photosensitive film adhesive further comprises a (C) radiation-polymerizable compound and a (D) photoinitiator.

5. The semiconductor device according to claim 3, wherein the (A) thermoplastic resin is an alkali-soluble resin.

6. The semiconductor device according to claim 5, wherein the alkali-soluble resin is a polyimide resin having a carboxyl and/or hydroxyl group in the molecule.

7. The semiconductor device according to claim 3, wherein the (B) thermosetting resin is an epoxy resin.

8. The semiconductor device according to claim 1, wherein the patterned photosensitive film adhesive is formed by:
an adhesive layer-forming step in which an adhesive layer comprising the photosensitive film adhesive is formed on an adherend,
an exposure step in which the adhesive layer is exposed with a prescribed pattern,
a developing step in which the exposed adhesive layer is developed with an aqueous alkali solution, and
a water content-adjusting step in which the water content of the developed adhesive layer is adjusted.

9. A method for producing a semiconductor device, comprising a patterning step in which a photosensitive film adhesive formed on the circuit side of a semiconductor element is patterned by exposure and development, a water content-adjusting step in which the water content of the patterned photosensitive adhesive is adjusted, and a thermocompression bonding step in which an adherend is directly bonded by thermocompression bonding to the patterned photosensitive adhesive,
wherein in the water content-adjusting step, water content adjustment is carried out in which the water content after pattern formation of the patterned photosensitive film adhesive on a PET substrate is adjusted to no greater than 1.0 wt %.

10. The method for producing a semiconductor device according to claim 9, wherein the adherend is a semiconductor element or protective glass.

11. The method for producing a semiconductor device according to claim 9, wherein the water content adjustment is heat treatment.

12. The method for producing a semiconductor device according to claim 9, wherein the photosensitive film adhesive comprises at least a (A) thermoplastic resin and a (B) thermosetting resin.

13. The method for producing a semiconductor device according to claim 12, wherein the photosensitive film adhesive further comprises a (C) radiation-polymerizable compound and a (D) photoinitiator.

14. The method for producing a semiconductor device according to claim 12, wherein the (A) thermoplastic resin is an alkali-soluble resin.

15. The method for producing a semiconductor device according to claim 14, wherein the alkali-soluble resin is a polyimide resin having a carboxyl and/or hydroxyl group in the molecule.

16. The method for producing a semiconductor device according to claim 12, wherein the (B) thermosetting resin is an epoxy resin.

17. A semiconductor device produced by the production method according to claim 9.
